(19) United States
(12) Patent Application Publication
(10) Pub. No.: US 2026/0150510 A1
(43) Pub. Date: May 28, 2026

(54) DISPLAY DEVICE, ELECTRONIC DEVICE INCLUDING THE DISPLAY DEVICE, AND MANUFACTURING METHOD OF THE DISPLAY DEVICE

(71) Applicant: Samsung Display Co., LTD., Yongin-si (KR)

(72) Inventors: DONG GYU BAECK, Yongin-si (KR); SE AH KWON, Yongin-si (KR); YOUNGSOO KWON, Yongin-si (KR); SUJIN KIM, Yongin-si (KR); WON-GAP YOON, Yongin-si (KR); KIHEON LEE, Yongin-si (KR); Yongju Hong, Yongin-si (KR)

(21) Appl. No.: 19/327,412

(22) Filed: Sep. 12, 2025

(30) Foreign Application Priority Data
Nov. 25, 2024 (KR) 10-2024-0169539

(51) Int. Cl. H10K 59/122; H10K 59/12; H10K 59/38; H10K 59/80

(52) U.S. Cl. CPC H10K 59/122; H10K 59/1201; H10K 59/38; H10K 59/8791

(57) ABSTRACT

A display device includes: a substrate including first to third light-emitting areas, and a non-light-emitting area surrounding the light-emitting areas; a first partition wall overlapping the non-light-emitting area, having a first height, and defining first to third central openings overlapping the first to third light-emitting areas, respectively; a second partition wall including first and second scattering partition walls in the first and second central openings, respectively, having a second height, and including a scattering body; a color conversion layer including a first color conversion pattern disposed adjacent to the first scattering partition wall in the first central opening and including an ink without the scattering body, and a second color conversion pattern disposed adjacent to the second scattering partition wall in the second central opening and including the ink without the scattering body; and a light-emitting layer between the substrate and the color conversion layer.

### BACKGROUND

This application claims priority to Korean Patent Application No. 10-2024-0169539, filed on Nov. 25, 2024, and all the benefits accruing therefrom under 35 U.S.C. § 119, the content of which in its entirety is herein incorporated by reference.

### 1. Field

The disclosure relates to a display device. More specifically, the disclosure relates to a manufacturing method of a display device including a quantum dot, a display device manufactured by the manufacturing method of the display device, and an electronic device including the display device.

### 2. Description of the Related Art

With the development of information technology, the importance of display devices, which are the medium of connection between users and information, is being highlighted. As a result, the use of display devices such as liquid crystal display devices “LCD”, organic light-emitting display devices “OLED”s, and plasma display devices “PDP”s is increasing.

The display device may include a color conversion layer on a light-emitting device. The color conversion layer may convert a wavelength of a light emitted from the light-emitting device. Accordingly, the display device may display an image by a combination of various color-light.

### SUMMARY

Embodiments provide a display device with improved display quality.

Other embodiments provide an electronic device including the display device.

Other embodiments provide a manufacturing method of the display device.

A display device according to an embodiment of the disclosure includes: a substrate including a first light-emitting area, a second light-emitting area, a third light-emitting area, and a non-light-emitting area surrounding the first light-emitting area, the second light-emitting area, and the third light-emitting area, a first partition wall disposed in the non-light-emitting area on the substrate, having a first height, and defining a first central opening overlapping the first light-emitting area, a second central opening overlapping the second light-emitting area, and a third central opening overlapping the third light-emitting area; a second partition wall including a first scattering partition wall disposed in the first central opening and a second scattering partition wall disposed in the second central opening, having a second height different from the first height, and including a scattering body, a color conversion layer including a first color conversion pattern, a second color conversion pattern, and a transparent pattern, the first color conversion pattern disposed adjacent to the first scattering partition wall in the first central opening and including an ink without the scattering body, the second color conversion pattern disposed adjacent to the second scattering partition wall in the second central opening and including the ink without the scattering body, and the transparent pattern disposed in the third central opening, and a light-emitting layer disposed between the substrate and the color conversion layer.

In an embodiment, the scattering body may include at least one or more oxides selected from a group consisting of TiO2, SiO2, BaSO4, ZnO, Al2O3, and CaCO3.

In an embodiment, the second height may be smaller than the first height.

In an embodiment, the display device may further include a color filter layer on the color conversion layer including a first color filter overlapping the first central opening, a second color filter overlapping the second central opening, and a third color filter overlapping the third central opening.

In an embodiment, the second partition wall may be provided in plurality in each of the first central opening and the second central opening.

In an embodiment, the first color filter, the second color filter, and the third color filter may cover the plurality of the second partition walls.

In an embodiment, the second partition wall may be provided in singularity in each of the first central opening and the second central opening.

In an embodiment, the second partition wall may be disposed to overlap each of a center of the first central opening and a center of the second central opening.

An electronic device according to an embodiment of the disclosure includes: a display device and a processor configured to control the display device. The display device includes a substrate including a first light-emitting area, a second light-emitting area, a third light-emitting area, and a non-light-emitting area surrounding the first light-emitting area, the second light-emitting area, and the third light-emitting area, a light-emitting layer on the substrate, a first partition wall overlapping the non-light-emitting area on the light-emitting layer, having a first height, and defining a first central opening overlapping the first light-emitting area, a second central opening overlapping the second light-emitting area, and a third central opening overlapping the third light-emitting area, a second partition wall including a first scattering partition wall disposed in the first central opening and a second scattering partition wall disposed in the second central opening, having a second height different from the first height, and including a scattering body, a color conversion layer including a first color conversion pattern, a second color conversion pattern, and a transparent pattern, the first color conversion pattern disposed adjacent to the first scattering partition wall in the first central opening and including an ink without the scattering body, the second color conversion pattern disposed adjacent to the second scattering partition wall in the second central opening and including the ink without the scattering body, and the transparent pattern disposed in the third central opening, and a color filter layer disposed on the color conversion layer, and including a first color filter overlapping the first central opening, a second color filter overlapping the second central opening, and a third color filter overlapping the third central opening.

In an embodiment, the scattering body may include at least one or more oxides selected from a group consisting of TiO2, SiO2, BaSO4, ZnO, Al2O3, and CaCO3.

In an embodiment, the second height may be smaller than the first height.

In an embodiment, the second partition wall may be provided in plurality in each of the first central opening and the second central opening.

In an embodiment, the first color filter, the second color filter, and the third color filter may cover the plurality of the second partition walls.

In an embodiment, the second partition wall may be provided in singularity in each of the first central opening and the second central opening.

In an embodiment, the second partition wall may include: one first scattering partition wall overlapping a center of the first central opening and one second scattering partition wall overlapping a center of the second central opening.

A manufacturing method of a display device according to an embodiment of the disclosure includes: forming a light-emitting layer on a substrate including a first light-emitting area, a second light-emitting area, a third light-emitting area, and a non-light-emitting area surrounding the first light-emitting area, the second light-emitting area, and the third light-emitting area, forming a first partition wall on the light-emitting layer, overlapping non-light-emitting area, having a first height, and defining a first central opening overlapping the first light-emitting area, a second central opening overlapping the second light-emitting area, and a third central opening overlapping the third light-emitting area, forming a preliminary partition wall including a scattering body in the first central opening, the second central opening, and the third central opening, forming a second partition wall by removing a portion of the preliminary partition wall in the first central opening and the second central opening, and forming a first color conversion pattern and a second color conversion pattern, wherein the first color conversion pattern is formed adjacent to the second partition wall in the first central opening and includes the ink without the scattering body, and the second color conversion pattern is formed adjacent to the second partition wall in the second central opening and includes the ink without the scattering body.

In an embodiment, the forming of the first color conversion pattern and the second color conversion pattern may include: jetting the ink without the scattering body in the first opening and the second opening, and exposing the ink.

In an embodiment, the forming of the second partition wall may include: forming a mask on the preliminary partition wall, and forming the second partition wall in plurality by patterning the second partition wall to have a second height smaller than the first height of the first partition wall using the mask.

In an embodiment, in case the second partition wall is provided in plurality in each of the first central opening and the second central opening, the method may further include: forming a second preliminary color filter layer on the color conversion layer, and forming a second color filter layer by removing a portion of the second preliminary color filter layer to cover the plurality of the second partition walls and overlap a portion of the first central opening, an entirety of the second central opening, and a portion of the third central opening, forming a first preliminary color filter layer on the second color filter layer, forming a first color filter layer by removing a portion of the first preliminary color filter layer to cover the plurality of the second partition walls and overlap an entirety of the first central opening, a portion of the second central opening, and a portion of the third central opening, forming a third preliminary color filter layer on the first color filter layer, and forming a third color filter layer by removing a portion of the third preliminary color filter layer to cover the plurality of the second partition walls and overlap a portion of the first central opening, a portion of the second central opening, and an entirety of the third central opening.

In an embodiment, the forming of the second partition wall may include forming a mask on the preliminary partition wall, and forming one first scattering partition wall and one second scattering partition wall by patterning the second partition wall to have a second height smaller than the first height of the first partition wall using the mask, where the first scattering partition wall overlaps the first central opening and the second scattering wall overlaps the second central opening.

In the display device, the electronic device, and the manufacturing method of the display device according to an embodiment of the disclosure may form a first sub pixel in which the first color conversion pattern including the second partition wall the first scattering partition wall including the scattering body and the ink without the scattering body, a second sub pixel in which the second color conversion pattern including the second partition wall the second scattering partition wall including the scattering body and the ink without the scattering body, and a third sub pixel in which the transparent pattern including the scattering body. Since the color conversion patterns do not include the scattering body, a reflection due to the scattering body may be prevented or minimized. In addition, a brightness may be increased. In addition, the scattering body may be prevented from being adsorbed to a nozzle. In addition, a viscosity of the ink may be reduced, so that an inkjet process may be carried out to form a display device of high resolution. The viscosity of the ink including the scattering body may be greater than the viscosity of the ink without the scattering body.

### BRIEF DESCRIPTION OF THE DRAWINGS

The above and other features of embodiments of the disclosure will become more apparent by describing in further detail embodiments thereof with reference to the accompanying drawings, in which:

FIGS. 1, 2, and 3 are views illustrating a display device according to embodiments of the disclosure.

FIG. 4 is a cross-sectional view taken along line I-I′ of FIG. 2.

FIG. 5 is a view illustrating a first embodiment of the color conversion layer of FIG. 4.

FIG. 6 is a view illustrating a second embodiment of the color conversion layer.

FIGS. 7 and 8 are views illustrating an effect of the display device according to embodiments of the disclosure.

FIGS. 9, 10, 11, 12, 13, 14, 15, 16, 17, 18, 19, 20, 21, 22, 23, and 24 are views illustrating the manufacture method of the display device according to a first embodiment of the disclosure.

FIGS. 25 and 26 are views illustrating the manufacturing method of the display device according to a second embodiment of the disclosure.

FIG. 27 is a block diagram illustrating an electronic device including the display device of FIG. 1.

FIG. 28 is a view illustrating an example in which the electronic device of FIG. 27 is implemented as a television.

FIG. 29 is a view illustrating an example in which the electronic device of FIG. 27 is implemented as a smartphone.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Hereinafter, display devices in embodiments will be described in more detail with reference to the accompanying drawings. The same reference numerals are used for the same components in the drawings, and any repetitive detailed descriptions of the same components will be omitted or simplified.

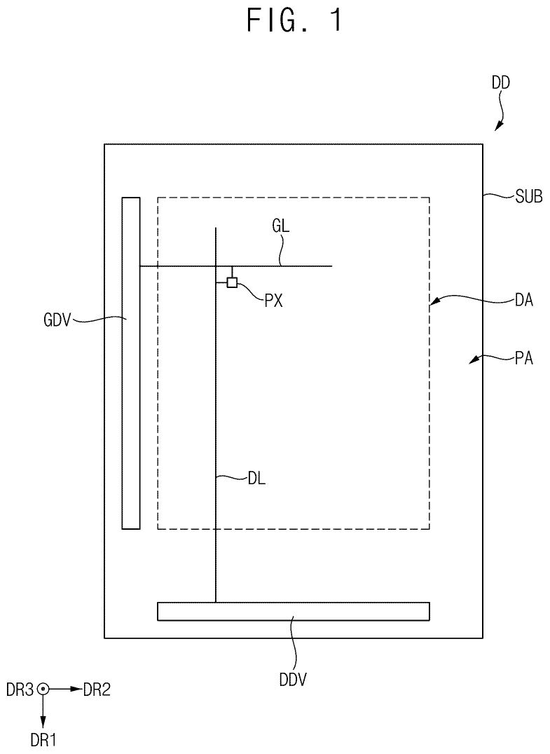

FIGS. 1, 2, and 3 are views illustrating a display device according to embodiments of the disclosure.

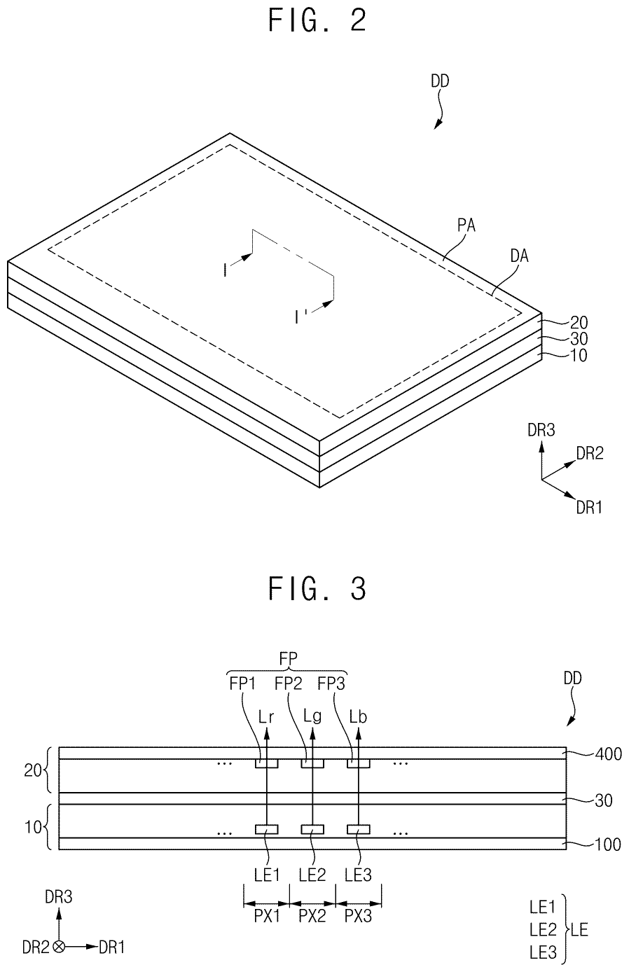

For example, FIG. 1 is a top view of a display DD, FIG. 2 is a perspective view of the display DD, and FIG. 3 is a schematic cross-sectional view of the display DD.

Referring to FIG. 1, the display device DD according to embodiments of the disclosure may include a substrate SUB, a plurality of pixels PX, a data line DL, a gate line GL, a gate driver GDV, and a data driver DDV.

The substrate SUB may include a display area DA and a peripheral area PA. The display area DA may be an area that may generate light or display an image by adjusting a transmittance of light provided from an external light source. The peripheral area PA may be the area that does not display the image. The peripheral area PA may be located on the periphery of the display area DA. For example, the peripheral area PA may surround the display area DA as a whole.

The plurality of pixels PX may be disposed in the display area DA on the substrate SUB. The plurality of pixels PX may be arranged in a matrix along a first direction DR1 and a second direction DR2 crossing the first direction DR1.

In the peripheral area PA on the substrate SUB, a driver may be disposed to drive the plurality of pixels PX. For example, the drivers may include the gate driver GDV and the data driver DDV.

The gate line GL may be electrically connected to the gate driver GDV and may be extended along the first direction DR1. The gate line GL may receive a gate signal from the gate driver GDV and may transmit the gate signal to the plurality of pixels PX.

The data line DL may be electrically connected to the data driver DDV and may be extended along the second direction DR2. The data line DL may receive a data voltage from the data driver DDV and may deliver the data voltage to the plurality of pixels PX.

For example, as shown of FIG. 1, the data driver DDV may be disposed directly on the substrate SUB. Alternatively, the data driver DDV may be disposed on a circuit board (e.g., a printed circuit board PCB or a flexible printed circuit board FPCB) electrically connected to a pad electrode disposed on one side of the peripheral area PA.

Herein, a plane may be defined as the first direction DR1 and the second direction DR2 crossing the first direction DR1. For example, the first direction DR1 and the second direction DR2 may be perpendicular to each other. In addition, a third direction DR3 may be perpendicular to the plane.

Referring to FIG. 2, for example, the display device DD may include a first panel 10, a second panel 20, and a connection layer 30. The first panel 10, the second panel 20, and the connection layer 30 included in the display device DD may have a structure stacked along the third direction DR3.

Referring to FIGS. 1 and 3, the one-pixel PX included in the display device DD may include a plurality of sub-pixels. For example, the sub-pixels may include a first sub-pixel PX1, a second sub-pixel PX2, and a third sub-pixel PX3 that emit light of different colors. Each of the sub-pixels may include a drive transistor that generates a drive current and a light-emitting device that is electrically connected to the drive transistor and generates light based on the drive current. Accordingly, each of the sub-pixels may emit light according to the drive current.

For example, the first sub-pixel PX1, the second sub-pixel PX2, and the third sub-pixel PX3 may emit light of different colors. For example, the first sub-pixel PX1 may emit a first color-light Lr (e.g., red light), and the second sub-pixel PX2 may emit a second color-light Lg (e.g., green light), the third sub-pixel PX3 may emit a third color-light Lb (e.g., blue light). However, the disclosure is not limited thereto.

For example, the display device DD may include the first panel 10, the second panel 20, and the connecting layer 30.

For example, the first panel 10 may include a lower substrate 100 and a light-emitting device LE.

The light-emitting device LE may be disposed on the lower substrate 100. For example, the light-emitting device LE may be disposed along the third direction DR3 of the lower substrate 100.

For example, the first sub-pixel PX1, the second sub-pixel PX2, and the third sub-pixel PX3 may include a light-emitting device LE, respectively. For example, the light-emitting device LE may be an organic light-emitting diode. For example, the first sub-pixel PX1 may include a first light-emitting device LE1. The first light-emitting device LE1 may be a first organic light-emitting diode. The second sub-pixel PX2 may include a second light-emitting device LE2. The second light-emitting device LE2 may be a second organic light-emitting diode. The third sub-pixel PX3 may include a third light-emitting device LE3. The third light-emitting device LE3 may be a third organic light-emitting diode.

For example, the first light-emitting device LE1, the second emitting-device LE2, and the third emitting-device LE3 may emit different colors of light. For example, the first emitting-device LE1 may emit red light, the second emitting-device LE2 may emit green light, and the third emitting-device LE3 may emit blue light. The disclosure is not limited thereto.

Alternatively, the first light-emitting device LE1, the second emitting-device LE2, and the third emitting-device LE3 may emit light of the same color. For example, the first emitting-device LE1, the second emitting-device LE2, and the third emitting-device LE3 may all emit blue light. For other examples, the first light-emitting device LE1, the second emitting-device LE2, and the third emitting-device LE3 may emit green and blue light.

For example, the second panel 20 may include an upper substrate 400 and a filter part FP.

The filter part FP may be located on the upper substrate 400. For example, the filter part FP may be disposed along an opposite direction to the third direction DR3 of the upper substrate 400.

For example, the filter part FP may include a first filter FP1, a second filter FP2, and a third filter FP3.The light emitted from the first light-emitting device LE1 may pass through the first filter FP1 and be emitted into the first light Lr. The light emitted from the second light-emitting device LE2 may pass through the second filter FP2 and be emitted into the second light Lg. The light emitted from the third light-emitting device LE3 may pass through the third filter FP3 and be emitted into the third light Lb.

The filter part FP may include a functional layer and a color filter layer. In an embodiment, the functional layer may include a first color conversion pattern, a second color conversion pattern, and a transparent pattern. In an embodiment, the color filter layer may include the first color filter, the second color filter, and the third color filter. The first filter FP1 may include the first color conversion pattern and the first color filter. The second filter FP2 may include the second color conversion pattern and the second color filter. The third filter FP3 may include the transparent pattern and the third color filter.

For example, the filter part FP may be formed on the upper substrate 400 to form the second panel 20, and then laminated with the first panel 10. In this case, the connecting layer 30 may include a filler that laminates the first panel 10 and the second panel 20. For example, the filler may include a thermo-setting material, a light-setting material, or the like. However, the disclosure is not limited thereto.

FIGS. 1 to 3 are illustrative, and the disclosure is not limited thereto.

For example, the display device DD may include only one substrate. For example, the display device DD may include only the lower substrate 100. In this case, the filter part FP may be formed on the first panel 10, and a coating layer may be formed. In other words, the coating layer may correspond to the upper substrate 400. By using the coating layer instead of the upper substrate 400, a light release efficiency may be increased, and curved panels may be implemented.

For example, the coating layer may include inorganic or organic material. For example, the inorganic material may include silicon oxide, silicon nitride, silicon oxide, or the like. The organic material may include epoxy resin, siloxane resin, photoresist, or the like. However, the disclosure is not limited thereto. For example, the coating layer may include various materials of high hardness.

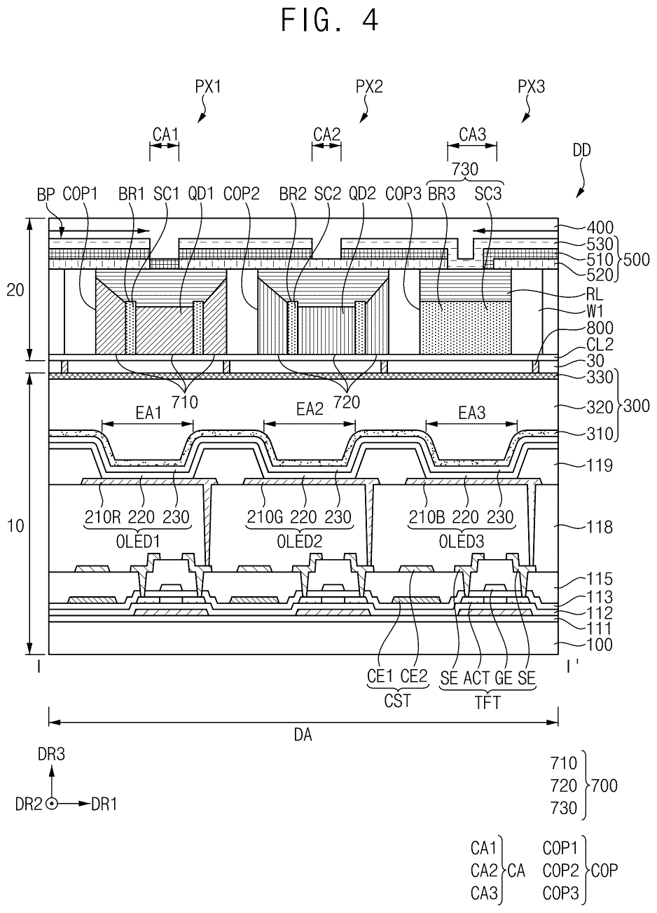

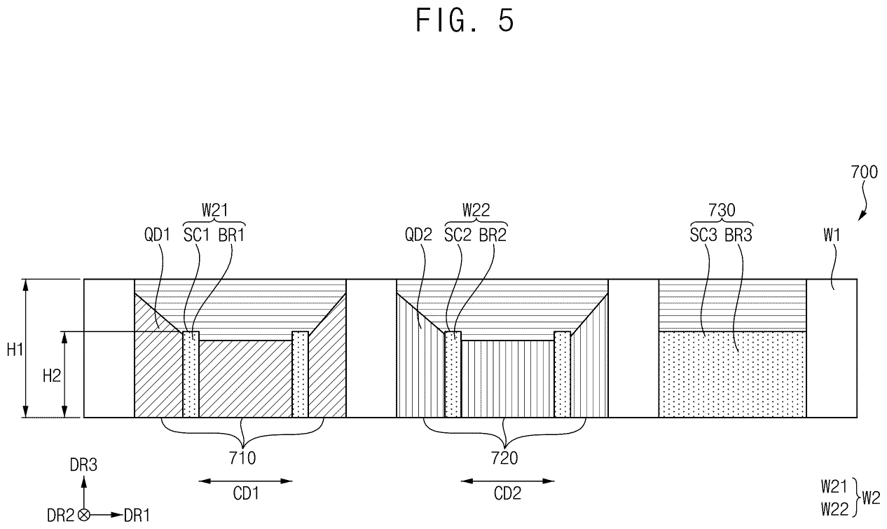

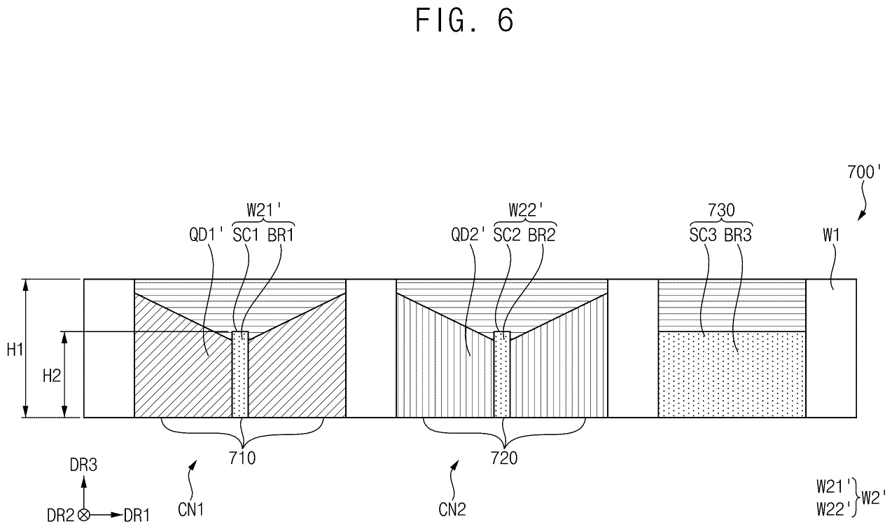

FIG. 4 is a cross-sectional view taken along line I-I′ of FIG. 2. FIG. 5 is a view illustrating a first embodiment of the color conversion layer of FIG. 4. FIG. 6 is a view illustrating a second embodiment of the color conversion layer.

Referring to FIGS. 4 and 5, the display device DD may include the first sub-pixel PX1, the second sub-pixel PX2, and the third sub-pixel PX3 disposed in the display area DA. However, the disclosure is not limited thereto. For example, the display device DD may include more sub-pixels.

For example, the first sub-pixel PX1, the second sub-pixel PX2, and the third sub-pixel PX3 may be disposed sequentially along the first direction DR1 (and the second direction DR2, refer to FIG. 1). However, the disclosure is not limited thereto. For example, the first sub-pixel PX1, the second sub-pixel PX2, and the third sub-pixel PX3 may not be adjacent to each other.

As described above, the display device DD may include the first panel 10, the second panel 20, and the connecting layer 30. Along the third direction DR3, the first panel 10, the connecting layer 30, and the second panel 20 may be disposed sequentially.

The first panel 10 may include the lower substrate 100, a first buffer layer 111, a bias electrode BSM, a second buffer layer 112, a thin film transistor TFT, a storage capacitor Cst, a gate insulating layer 113, an interlayer insulating layer 115, a planarization layer 118, a light-emitting device, and an encapsulation layer 300. Thin film transistor TFT may include active pattern ACT, a gate electrode GE, a source electrode SE, and a drain electrode DE. The storage capacitors Cst may include a first electrode CE1 and a second electrode CE2.

For example, the lower substrate 100 may include a material having a rigid property. For example, the material having the rigid property may include glass, metal, ceramic, or the like. Another example, the lower substrate 100 may include a material having a flexible(bendable/slidable) property. For example, the material having the flexible(bendable/slidable) property may include a polyether sulfone, polyacrylate, polyetherimide, polyethylene naphthalate, polyethylene terephthalate, polyphenylene sulfide, polyarylate, polyimide, polycarbonate, cellulose acetate propionate. However, the disclosure is not limited thereto.

For example, the lower substrate 100 may have a multi-layer structure. For example, the multi-layer structure may include organic, inorganic, and organic material sequentially. However, the disclosure is not limited thereto. For example, the number, order, or the like. of the organic and/or inorganic layers may vary variously. Alternatively, the lower substrate 100 may have a single-layer structure.

An additional barrier layer may be further included between the lower substrate 100 and the first buffer layer 111. The barrier layer may prevent or minimize a penetration of impurities from the lower substrate 100 into the active pattern ACT. For example, the barrier layer may include inorganic, organic, or organic and inorganic compounds. For example, the barrier layer may have a multi-layer structure. However, the disclosure is not limited thereto. Alternatively, the barrier layer may have a single-layer structure.

The bias electrode BSM may be disposed on the first buffer layer 111. The bias electrode BSMs may be disposed in locations corresponding to the thin film transistor TFT, for example, the bias electrode BSM may be subjected to voltage. In addition, the bias electrode BSM may prevent external light from reaching the active pattern ACT. As a result, the property of the thin film transistor TFT may be stabilized. Alternatively, the bias electrode BSM may be omitted.

The active pattern ACT may be disposed on the second buffer layer 112. The active pattern ACT may include amorphous silicon or crystalline crystallized/poly silicon. However, the disclosure is not limited thereto. For example, the oxide may include at least one or more oxides selected from the group consisting of indium (“In”), gallium (“Ga”), tin Sn, zirconium (“Zr”), vanadium (“V”), hafnium (“Hf”), cadmium (“Cd”), germanium (“Ge”), chromium (“Cr”), titanium (“Ti”), aluminum (“Al”), cesium (“Cs”), cerium (“Ce”) and zinc (“Zn”). For example, the active pattern ACT may include zinc oxide. In this case, the zinc oxide may include IZO (In—Zn—O), IGZ (In—Ga—Zn), IGZO (In—Ga—Zn—O), ITZO (In—Sn—Zn—O), IGZO (In—Ga—Sn—Zn—O), IGZO (In—Ga—Sn—Zn—O), or the like.

The active pattern ACT may include a channel area, a source area, and a drain area. The channel area may be located between the source area and the drain area. For example, the active pattern ACT may have a single-layer or multi-layer structure.

The gate electrode GE may be disposed on the active pattern ACT. The gate electrode GE may overlap at least a portion of the active pattern ACT. The gate electrode GE may include molybdenum (“Mo”), aluminum (“Al”), copper (“Cu”), titanium (“Ti”), or the like. However, the disclosure is not limited thereto. For example, the gate electrode GE may have a single-layer or multi-layer structure.

The gate insulating layer 113 may be disposed between the active pattern ACT and the gate electrode GE so that the active pattern ACT and the gate electrode GE may be insulated.

The first electrode CE1 may be disposed on the same level as the gate electrode GE. For example, the first electrode CE1 and the gate electrode GE may include the same material. In other words, the first electrode CE1 and the gate electrode GE may be formed in the same process. For example, the first electrode CE1 and the gate electrode GE may include molybdenum (“Mo”). However, the disclosure is not limited thereto. The first electrode CE1 may make up the storage capacitor Cst.

However, the disclosure is not limited thereto. For example, the storage capacitor Cst may overlap the thin film transistor TFT. In this case, the gate electrode GE of the thin film transistor TFT may correspond to the first electrode CE1 of the storage capacitor Cst.

The interlayer insulating layer 115 may be disposed on the gate electrode GE and the first electrode CE1. For example, the interlayer insulating layer 115 may include silicon oxide (“SiO₂”), silicon nitride (“SiNₓ”), silicon oxide (“SiON”), aluminum oxide (“Al₂O₃”), titanium oxide (“TiO₂”), tantalum oxide (“Ta₂O₅”), hafnium oxide (“HfO₂”), or zinc oxide (“ZnOₓ”). The zinc oxide (“ZnOₓ”) may include zinc oxide (“ZnO”) and zinc peroxide (“ZnO₂”). However, the disclosure is not limited thereto.

On the interlayer insulating layer 115, the second electrode CE2, the source electrode SE, and the drain electrode DE of the storage capacitor Cst may be disposed. The second electrode CE2, the source electrode SE, and the drain electrode DE may include a conductive material. For example, the conductive material may include molybdenum (“Mo”), aluminum (“Al”), copper (“Cu”), titanium (“Ti”), or the like. For example, the second electrode CE2, the source electrode SE, and the drain electrode DE may have a single-layer or multi-layer structure. For example, the second electrode CE2, the source electrode SE, and the drain electrode DE may have a multi-layer structure in which the layers including titanium (“Ti”), aluminum (“Al”), and titanium (“Ti”) are stacked sequentially. However, the disclosure is not limited thereto. The source electrode SE may access the source area of the active pattern ACT through a contact hole. In addition, the drain electrode DE may access the drain area of the active pattern ACT through a contact hole.

The second electrode CE2 of the storage capacitor Cst may overlap the first electrode CE1. The second electrode CE2 may form the storage capacitor Cst. The interlayer insulating layer 115 may be disposed between the first electrode CE1 and the second electrode CE2. Accordingly, the interlayer insulating layer 115 may function as a dielectric layer of the storage capacitor Cst.

The planarization layer 118 may be disposed on the second electrode CE2, the source electrode SE, and the drain electrode DE. For example, the planarization layer 118 may include organic material. For example, the organic material may include a general-purpose polymer, a polymer derivative having a phenolic group, an acrylic polymer, an imide polymer, an aryl ether polymer, an amide polymer, a fluorine polymer, a p-xylene polymer, a vinyl alcohol polymer, or the like. For example, the general-purpose polymer is benzo cyclobutene (“BCB”), a polyimide, hexamethyldisiloxane (“HMDSO”), polymethylmethacrylate (“PMMA”), polystyrene (“PS”), or the like. Each of these may be used alone or in combination with each other. For example, the planarization layer 118 may have a single-layer or multi-layer structure. The planarization layer 118 may provide a flat surface.

The light-emitting device (e.g., the light-emitting device LE of FIG. 3) may be disposed on the planarization layer 118. The light-emitting device may include a pixel electrode, a light-emitting layer 220, and an opposing electrode 230.

For example, a first organic light-emitting diode OLED1, a second organic light-emitting diode OLED2, and a third organic light-emitting diode OLED3 may be disposed on the planarization layer 118. The first organic light-emitting diode OLED1 may include a first pixel electrode 210R. The second organic light-emitting diode OLED2 may include a second pixel electrode 210G. The third organic light-emitting diode OLED3 may include a third pixel electrode 210B. For example, the first organic light-emitting diode OLED1, the second organic light-emitting diode OLED2, and the third organic light-emitting diode OLED3 may have the light-emitting layer 220 and the opposing electrode 230 in common.

For example, the first pixel electrode 210R, the second pixel electrode 210G, and the third pixel electrode 210B may be disposed on the planarization layer 118. The first pixel electrode 210R, the second pixel electrode 210G, and the third pixel electrode 210B may be connected to the thin film transistor TFT, respectively. The first pixel electrode 210R, the second pixel electrode 210G, and the third pixel electrode 210B may include a semi-light-transmitting or reflective material. For example, the reflective material may include silver (“Ag, magnesium (“Mg”), aluminum (“Al”), platinum (“Pt”), palladium (“Pd”), gold (“Au”), nickel (“Ni”), neodymium (“Nd”), iridium (“Ir”), For example, the semi-light-transmitting material may include indium tin oxide (“ITO”), indium zinc oxide (“IZO”), zinc oxide (“ZnO”), indium oxide (“In₂O₃”), indium gallium oxide (“IGO”), aluminum zinc oxide (“AZO”), or the like. These may be used alone or in combination with each other. For example, the first pixel electrode 210R, the second pixel electrode 210G, and the third pixel electrode 210B may have a single-layer or multi-layer structure. For example, the first pixel electrode 210R, the second pixel electrode 210G, and the third pixel electrode 210B may have a structure in which the reflective layer and the semi-light-transmitting layer on the reflective layer are stacked sequentially. For example, the first pixel electrode 210R, the second pixel electrode 210G, and the third pixel electrode 210B may have a multi-layer structure in which the layers including the ITO, the Ag, and the ITO are stacked sequentially.

A pixel defining layer 119 may be disposed on the planarization layer 118. The pixel defining layer 119 may define openings exposing a central portion of the first pixel electrode 210R, the second pixel electrode 210G, and the third pixel electrode 210B, respectively.

In addition, the pixel defining layer 119 may cover edges of the first pixel electrode 210R, the second pixel electrode 210G, and the third pixel electrode 210B. The edges of the first pixel electrode 210R, the second pixel electrode, and the third pixel electrode 210B may be covered by the pixel defining layer 119, so that the edges of the pixel electrodes may be increased in distance from the opposing electrode 230. Arcing at the edge of the first pixel electrode 210R, second pixel electrode 210G, and third pixel electrode 210B may be prevented.

For example, the pixel defining layer 119 may include an organic insulating material. For example, the organic insulating material may include polyimide, polyamide, acrylic resin, benzo cyclobutene (“BCB”), phenolic resin, or the like. For example, the pixel defining layer 119 may be formed through a process such as spin coating.

For example, the light-emitting layer 220 may include organic material including the fluorescent or phosphorescent material. For example, the organic material may emit light such as red, green, blue, white, or the like.

For example, light-emitting layer 220 may include plurality of layers of light-emitting materials. The light-emitting layer 220 may include three layers of blue light-emitting material and one layer of green light-emitting material. In this case, the light-emitting efficiency may be higher than if only the blue light-emitting material layer was included. However, the disclosure is not limited thereto.

For example, the functional layer may be further disposed above and below the light-emitting layer 220. For example, the functional layer may include a hole transport layer HTL, a hole injection layer HIL, an electron transport layer ETL, and an electron injection layer EIL. For example, the light-emitting layer 220 and the functional layer may have a structure, which a first hole transport layer, a first blue light-emitting material layer, a first electron transport layer, a first charge-generating layer, a second hole transport layer, a second blue-emitting material layer, a second electron transport layer, a second charge-generating layer, a third hall transport layer, a third blue light-emitting material layer, a third electron transport layer, a third charge-generating layer, a fourth-hole transport layer, a green light-emitting material layer, and a fourth electron transport layer sequentially stacked. However, the disclosure is not limited thereto.

For example, the light-emitting layer 220 may be formed integrally across the first pixel electrode 210R, the second pixel electrode 210G, and the third pixel electrode 210B. However, the disclosure is not limited thereto. Alternatively, the light-emitting layer 220 may be positioned in response to the first pixel electrode 210R, the second pixel electrode 210G, and the third pixel electrode 210B, respectively. For example, the light-emitting layer 220 may be formed through a patterning process to correspond to the first pixel electrode 210R, the second pixel electrode 210G and the third pixel electrode 210B, respectively.

For example, light-emitting layer 220 may emit light of the first color. For example, the first color may have a wavelength in a first wavelength band. For example, the first color may be blue. In this case, the first wavelength band may be about 450 nanometers (“nm”) to about 500 nanometers. However, the disclosure is not limited thereto.

As described above, the light-emitting layer 220 may emit light of the first and second colors. For example, the first color may have a wavelength in the first wavelength band, and the second color may have a wavelength in a second wavelength band. For example, the first color may be blue, and the second color may be green. In this case, the first wavelength band may be about 450 nanometers to about 500 nanometers, the second wavelength band may be about 520 nanometers to about 570 nanometers.

The opposite electrode 230 may be disposed on the light-emitting layer 220. The opposing electrode 230 may be positioned to correspond to the first pixel electrode 210R, the second pixel electrode 210G, and the third pixel electrode 210B. For example, the opposing electrode 230 may be formed as a one-body in a plurality of the organic light-emitting diodes.

For example, the opposing electrode 230 may include a transparent or semi-transparent material. The semi-transparent material may include lithium (“Li”), calcium (“Ca”), aluminum (“Al”), silver (“Ag”), magnesium (“Mg”), or the like. Each of these may be used alone or in combination with each other. However, the disclosure is not limited thereto. For example, the opposing electrode 230 may include various metal materials with small work functions. For example, the opposing electrode 230 may have a single-layer or multi-layer structure. For example, a transparent conductive oxide layer may be further included on the metal thin film including LiF/Al. For example, the transparent conductive oxide may include ITO, IZO, ZnO, In₂O₃, or the like. However, the disclosure is not limited thereto.

For example, the first light may be generated in a first light-emitting area EA1 of the first organic light-emitting diode OLED1 and emitted to the outside. The first light-emitting area EA1 may be defined as a portion of the first pixel electrode 210R that overlaps the opening of the pixel defining layer 119. The second light may be generated in a second light-emitting area EA2 of the second organic light-emitting diode OLED2 and emitted to the outside. The second light-emitting area EA2 may be defined as a portion of the second pixel electrode 210G that overlaps by the opening of the pixel defining layer 119. The third light may be generated in a third light-emitting area EA3 of the third organic light-emitting diode OLED3 and emitted to the outside. The third light-emitting area EA3 may be defined as a portion of the third pixel electrode 210B that overlaps the opening of the pixel defining layer 119.

The first light-emitting area EA1, the second light-emitting area EA2, and the third light-emitting area EA3 may be spaced from each other. Among the display area DA, the area other than the first light-emitting area EA1, the second light-emitting area EA2, and the third light-emitting area EA3 may be a non-light-emitting area. The first light-emitting area EA1, the second light-emitting area EA2, and the third light-emitting area EA3 may be divided by the non-light-emitting area. In the plan view, the first light-emitting area EA1, the second light-emitting area EA2, and the third light-emitting area EA3 may be arranged in various arrangements, such as stripes, pentiles, or the like. In the plan view, the shape of the first light-emitting area EA1, the shape of the second light-emitting area EA2, and the shape of the third light-emitting area EA3 may have various shapes such as polygons, circles, ellipses, or the like.

The pixel defining layer 119 may further include a spacer. The spacer may prevent a stamping by a mask. For example, the spacer may be formed as one-body with the pixel defining layer 119. For example, the spacer and the pixel defining layer 119 may be formed simultaneously in the same process using a half-tone mask process. However, the disclosure is not limited thereto.

The encapsulation layer 300 may be disposed on the light-emitting device. The encapsulation layer 300 may cover the light-emitting device (e.g., first organic light-emitting diode OLED1, second organic light-emitting diode OLED2, and third organic light-emitting diode OLED3). The light-emitting device may be easily damaged by external moisture, oxygen, or the like. The encapsulation layer 300 may cover the light-emitting device to protect it from the moisture, oxygen, or the like. For example, the encapsulation layer 300 may extend to the display area DA and an outer part of the display area DA (i.e., a portion of the peripheral area PA of FIG. 1).

The encapsulation layer 300 may have a multi-layer structure. For example, the encapsulation layer 300 may include a first inorganic encapsulation layer 310, an organic encapsulation layer 320, and a second inorganic encapsulation layer 330.

The first inorganic encapsulation layer 310 and the second inorganic encapsulation layer 330 may include an inorganic material. For example, the inorganic material may include aluminum oxide (“Al₂O₃”), titanium oxide (“TiO₂”), tantalum oxide (“Ta₂O₅”), hafnium oxide (“HfO₂”), zinc oxide (“ZnOₓ”), silicon oxide (“SiO₂”), silicon nitride (“SiNₓ”), silicon oxide (“SiON”), or the like.

The organic encapsulation layer 320 may include a polymer-like material. For example, the polymer-like material may include acrylic resin, epoxy resin, polyimide, polyethylene, or the like. For example, the organic encapsulation layer 320 may include the acrylate.

The inorganic layer (e.g., the first inorganic encapsulation layer 310 and/or the second inorganic encapsulation layer 330) may have a great property of preventing the penetration of the moisture, or the like. For example, in the case of the inorganic single layer structure, if a pinhole is generated by a particle, the moisture may easily penetrate through the pinhole.

To prevent this, an occurrence of the pinhole may be prevented or minimized by treating a surface of the inorganic material, or at least one or more organic layers (e.g., organic encapsulation layer 320) may further be disposed on the inorganic layer (e.g., the first inorganic encapsulation layer 310). Accordingly, an occurrence of dark spot or the like may be more prevented or minimized by increasing a penetrating path of the moisture of the like, and the upper surface may be flatted by including the organic material.

Accordingly, the first panel 10 including the lower substrate 100, the first buffer layer 111, the bias electrode BSM, the second buffer layer 112, the thin film transistor TFT, the storage capacitor Cst, the gate insulating layer 113, the interlayer insulating layer 115, the planarization layer 118, the light-emitting device, and the encapsulation layer 300 may be formed.

However, this is illustrative, and the disclosure is not limited thereto. Some of the components may be omitted/substituted or other components may be included. For example, between the encapsulation layer 300 and the opposite electrode 230, other layers such as a capping layer may be included.

As described above, if only one substrate is included, the process of forming the second panel 20 on the encapsulation layer 300 may proceed. Hereinafter, descriptions focusing on the display device DD formed through a process of forming the second panel 20 separately and then laminating the second panel 20 to the first panel 10 through the connecting layer 30.

For example, the second panel 20 may include the upper substrate 400, a color filter layer 500, a refractive layer RL, a first capping layer CL1, a first partition wall W1, a color conversion layer 700, and a second capping layer CL2.

In a cross-sectional view, the upper substrate 400 may be disposed on the light-emitting device (e.g., the first organic light-emitting diode OLED1, the second organic light-emitting diode OLED2, and the third organic light-emitting diode OLED3). That is, along the third direction DR3, the lower substrate 100, the light-emitting device, and the upper substrate 400 may be located sequentially. For example, the cross-section may be defined by the first direction DR1 and the third direction DR3.

The upper substrate 400 may include a central area CA overlapping the light-emitting device. For example, the central area CA may include a first central area CA1, a second central area CA2, and a third central area CA3. In the plan view, the first central area CA1 may overlap the first organic light-emitting diode OLED1 and/or the first light-emitting area EA1. The second central area CA2 may overlap the second organic light-emitting diode OLED2 and/or the second light-emitting area EA2. The third central area CA3 may overlap the third organic light-emitting diode OLED3 and/or the third light-emitting area EA3. As described above, the plane may be defined by the first direction D R1 and the second direction DR2.

For example, the upper substrate 400 may include a material having a rigid property. For example, the material having the rigid property may include glass, metal, ceramic, or the like. Another example, the upper substrate 400 may include a material having a flexible(bendable/slidable) property. For example, the material having the flexible(bendable/slidable) property may include a polyether sulfone, polyacrylate, polyetherimide, polyethylene naphthalate, polyethylene terephthalate, polyphenylene sulfide, polyarylate, polyimide, polycarbonate, cellulose acetate propionate. However, the disclosure is not limited thereto. For example, the upper substrate 400 may have a single-layer or multi-layer structure.

Hereinafter, for convenience of description, the opposite direction to the third direction DR3 may also be referred to as the “upper direction”.

The color filter layer 500 may be disposed on the upper substrate 400. The color filter layer 500 may include a first color filter 510, a second color filter 520, and a third color filter 530. The part of the first color filter 510 not overlapping with the second and third color filters 520 and 530 may be disposed in the first central area CA1. The part of the second color filter 520 not overlapping with the first and third color filters 510 and 530 may be disposed in the second central area CA2. The part of the third color filter 530 not overlapping with the first and second color filters 510 and 520 may be disposed in the third central area CA3. The first color filter 510, the second color filter 520, and the third color filter 530 may include a photosensitive resin, a dye, or the like. The first color filter 510, the second color filter 520, and the third color filter 530 each may include a different dye.

For example, the first color filter 510 may pass only light at wavelengths belonging to about 630 nanometers (nm) to about 780 nm (hereinafter, the third wavelength band). The second color filter 520 may pass through only light of wavelengths belonging to about 520 nm to about 570 nm (i.e., the second wavelength band), and the third color filter 530 may pass only light at wavelengths belonging to about 450 nm to about 500 nm (i.e., the first wavelength band). However, the disclosure is not limited thereto. The numerical range may be changed depending on the resin, the dye, or the like.

The color filter layer 500 may minimize a reflection of an external light of the display DD. For example, when the external light reaches the first color filter 510, only the light (hereinafter, transmitted light) of the third wavelength band described above may pass through the first color filter 510, and light with any other wavelength may be absorbed by the first color filter 510. A portion of the transmitted light may be reflected from the opposing electrode 230 and/or the first pixel electrode 210R and emitted back to the outside. Since only the portion of the transmitted light of the external light incident to a position of the first subpixel PX1 is reflected outward, the reflection of the external light may be minimized. The second color filter 520 and the third color filter 530 likewise reflect outward only a portion of the transmitted light of the external light incident to a position of the second sub-pixel PX2 and the third sub-pixel PX3, the reflection of the external light may be minimized.

A portion of the first color filter 510, a portion of the second color filter 520, and a portion of the third color filter 530 may overlap each other. For example, the first color filter 510, the second color filter 520, and the third color filter 530 may overlap between any one of the central areas CA and the other of the central areas CA. For example, the first color filter 510, the second color filter 520, and the third color filter 530 may overlap between the first central area CA1 and the second central area CA2. In this case, a part of the third color filter 530 may be disposed between the first central area CA1 and the second central area CA2. The first color filter 510 may extend from the first central area CA1 and may overlap the third color filter 530 between the first central area CA1 and the second central area CA2. The second color filter 520 may extend from the second central area CA2 and may overlap the third color filter 530 between the first central area CA1 and the second central area CA2.

The first color filter 510, the second color filter 520, and the third color filter 530 may overlap between the second central area CA2 and the third central area CA3. A part of the first color filter 510 may be disposed between the second central area CA2 and the third central area CA3. The second color filter 520 may extend from the second central area CA2 and may overlap the first color filter 510 between the second central area CA2 and the third central area CA3. The third color filter 530 may extend from the third central area CA3 and may overlap the first color filter 510 between the second central area CA2 and the third central area CA3.

The first color filter 510, the second color filter 520, and the third color filter 530 may overlap between the third central area CA3 and the first central area CA1. A part of the second color filter 520 may be disposed between the third central area CA3 and the first central area CA1. The third color filter 530 may extend from the third central area CA3 and may overlap the second color filter 520 between the third central area CA3 and the first central area CA1. The first color filter 510 may extend from the first central area CA1 and may overlap the second color filter 520 between the third central area CA3 and the first central area CA1.

The first color filter 510, the second color filter 520, and the third color filter 530 may overlap each other to form a light-shading area BP. Accordingly, the color filter layer 500 may prevent or minimize mixing of lights emitted from different organic light-emitting diodes without a separate shading member.

For example, the third color filter 530 may be most adjacent to the upper substrate 400. The third color filter 530 may absorb some of the external light to minimize the reflectivity of the display DD, and the reflected light from the third color filter 530 may be almost unapparent to a user. Thus, the third color filter 530 may be closest to the upper substrate 400. However, the disclosure is not limited thereto.

The refractive layer RL may be disposed in the central area CA. The refractive layer RL may be disposed in the first central area CA1, the second central area CA2, and the third central area CA3. For example, the refractive layer RL may include organic material. For example, a refractive index of the refractive layer RL may be less than a refractive index of the color filter layer 500. Accordingly, the refractive layer RL may concentrate light.

For example, a first capping layer may be disposed on the color filter layer 500. The first capping layer may be disposed between the color filter layer 500 and the color conversion layer 700. The first capping layer may protect the refractive layer RL and the color filter layer 500. The first capping layer may prevent or minimize the penetration of the impurities such as the moisture and/or the air from the outside to damage or contaminate the refractive layer RL and/or the color filter layer 500. For example, the first capping layer may include inorganic material.

The first partition wall W1 may be disposed on the color filter layer 500. The first partition wall W1 may be disposed on the surface of the upper substrate 400 opposite the lower substrate 100. For example, the first partition wall W1 may include organic material. For example, the first partition wall W1 may include a light-shielding material. For example, the light-shading material may include a black pigment, a black dye, a black particle, a black metal particle, or the like. These may be used alone or in combination with each other. However, the disclosure is not limited thereto.

The first partition wall W1 may define a plurality of openings. For example, the first partition wall W1 may define a central opening COP. The central opening COP may overlap the central area CA. For example, the central opening COP may include a first central opening COP1, a second central opening COP2, and a third central opening COP3. For example, the first central opening COP1 may overlap the first central area CA1. The second central opening COP2 may overlap the second central area CA2. The third central opening COP3 may overlap the third center area CA3.

The color conversion layer 700 may be disposed in the central opening COP. The color conversion layer 700 may fill the central opening COP. For example, the color conversion layer 700 may include a color conversion material, a scattering body, or the like. For example, the color conversion material may include a quantum dot (“QD”).

In an embodiment, the color conversion layer 700 may include a first color conversion pattern 710, a second color conversion pattern 720, a transparent pattern 730, and the second partition wall W2. The second partition wall W2 may include a first scattering partition wall W21 and a second scattering partition wall W22.

In an embodiment, the first sub-pixel PX1 may include the first organic light-emitting diode OLED1, the first color conversion pattern 710, and the first scattering partition wall W21.

In an embodiment, the first scattering partition wall W21 and the first color conversion pattern 710 may be disposed in the first central opening COP1. The first scattering partition wall W21 and the first color conversion pattern 710 may overlap the first central area CA1. The first scattering partition wall W21 and the first color conversion pattern 710 may also overlap the first light-emitting area EA1.

In an embodiment, a second height H2 of the second partition wall W2 may be different from a first height H1 of the first partition wall W1. In detail, in an embodiment, the second height H2 of the second partition wall W2 may be smaller than the first height H1 of the first partition wall W1. That is, the first partition wall W1 may be greater than the second partition wall W2. The first scattering partition wall W21 may be disposed in the first central opening COP1, and remaining area may be filled with the first color conversion pattern 710.

In an embodiment, the first scattering partition wall W21 may include a first scattering body SC1 and a first base resin BR1. The first scattering body SC1 may be in dispersed form in the first base resin BR1.

In an embodiment, the scattering body may include TiO₂, SiO₂, BaSO₄, ZnO, Al₂O₃, and CaCO₃, or the like. However, the disclosure is not limited thereto. For example, the scattering body may include a variety of light scattering particles. The scattering body may scatter the light so that more light may be emitted (i.e., it may improve the light-emitting efficiency).

For example, a size of the scattering body may be of about 500 nanometers or less. For example, if the size of the scattering body exceeds about 500 nanometers, it may be difficult to scatter the light emitted from the light-emitting layer 220.

For example, the first base resin BR1 may include a photosensitive polymer. For example, the first base resin BR1 may include silicone resin, acrylic resin, benzo cyclobutene (“BCB”), hexamethyldisiloxane (“HMDSO”), or the like.

For example, the first base resin BR1 may include a variety of material that are transparent and fluid-repellent. For example, the fluid-repellent material may include fluorine-based compounds or siloxane-based compounds. Accordingly, the scattering may be dispersed and typo deposition of an ink jetting forming the first color conversion pattern 710 may be prevented.

In an embodiment, the first color conversion pattern 710 may be formed through an inkjet process involving a first quantum dot QD1 and a first solvent. The first quantum dot QD1 may be in the dispersed form in the first solvent.

In other words, in an embodiment, the first color conversion pattern 710 does not include the scattering particle, and only the first scattering partition wall W21 may include the scattering particle (e.g., the first scattering particle SC1).

For example, the first color conversion pattern 710 may convert the light of the first wavelength band generated by the light-emitting layer 220 included in the first organic light-emitting diode OLED1 to the light of the third wavelength band. For example, light of wavelength belonging to about 450 nm to about 500 nm may be emitted from the light-emitting layer 220 on the first pixel electrode 210R. The light may be converted into light of wavelength belonging to about 630 nm to about 780 nm while passing through the first color conversion pattern 710. Thus, in the first sub-pixel PX1, light of wavelengths ranging from about 630 nm to about 780 nm may be emitted outward through the upper substrate 400. However, the disclosure is not limited thereto. As described above, the first organic light-emitting diode OLED1 may emit both the first wavelength band and the second wavelength band.

In an embodiment, the second partition wall W2 may be disposed plurality in the first central opening COP1. For example, the first scattering partition wall W21 may be positioned twice to have a first critical dimension CD1 in the first central opening COP1. For example, the first critical dimension CD1 may be between about 2 micrometers and about 3 micrometers. For example, if the first critical dimension CD1 is less than about 2 micrometers or exceeds about 3 micrometers, light may not be transmitted, or the reflectivity may increase. However, the disclosure is not limited thereto. For example, the first critical dimension CD1 value may be changed in various ways depending on the size of the display device DD (e.g., the display device DD of FIG. 1).

For example, if the reflectivity is large, the user's face may be visible on a black screen of the display device DD.

As described above, along the third direction DR3, the color conversion layer 700 may be located on the first panel 10, and the color filter layer 500 may be located on the color conversion layer 700. In an embodiment, the color filter layer 500 may include the first color filter 510 overlapping the first central opening COP1, the second color filter 520 overlapping the second central opening COP2, and the third color filter 530 overlapping the third central opening COP3.

In an embodiment, the color filter layer 500 may be arranged to cover the second partition wall W2. For example, at the position overlapping the first central opening COP1, the first color filter 510 may be continuously extended, and the second color filter 520 and the third color filter 530 may be partially removed to form a fourth opening.

If a width of the fourth opening (e.g., a width in the first direction DR1) is greater than the first critical dimension CD1, a portion of the incident external light incident with the first color filter 510 may be reflected from the first scattering partition wall W21, and increasing the reflectivity of the display device. To prevent this, the width of the fourth opening (e.g., a width in the first direction DR1) may be smaller than the first critical dimension CD1

The display device DD according to embodiments of the disclosure may prevent or minimize the increase in the reflectivity (e.g., the reflectivity by the first scattering partition wall W21) by the light-shading area BP, in which the first color filter 510, the second color filter 520, and the third color filter 530 are overlapped on each other and which covers the first scattering partition wall W21.

For example, a color conversion layer 700′ of FIG. 6 may differ in the number and position of the second partition wall W2 from the color conversion layer 700 of FIGS. 4 and 5. Therefore, hereinafter, overlapping descriptions may be omitted or simplified.

Referring to FIGS. 4 and 6, in an embodiment, the number of the first scattering partition wall W21′ may be one and the one first scattering partition wall W21′ may be disposed in the first central opening COP1. In an embodiment, the first scattering partition wall W21′ may be positioned overlapping a center CN1 of the first central opening COP1.

For example, a display device including the first scattering partition wall W21′ overlapping the center CN1 of the first central opening COP1 may result in a lower manufacturing cost than a display including a plurality of the first scattering partition walls W21. In addition, the first scattering partition wall W21′ may scatter the light to evenly adjust the brightness of a front and sides. In the case of the first scattering partition wall W21′ of FIG. 6 might not be covered by the light-shading area BP.

Referring to 4 and 5, in an embodiment, the second sub-pixel PX2 may include the second organic light-emitting diode OLED2, the second color conversion pattern 720, and the second scattering partition wall W22.

In an embodiment, the second scattering partition wall W22 and the second color conversion pattern 720 may be disposed in the second central opening COP2. The second scattering partition wall W22 and the second color conversion pattern 720 may overlap the second central area CA2. The second scattering partition wall W22 and the second color conversion pattern 720 may also overlap the second light-emitting area EA2.

In an embodiment, the second height H2 of the second partition wall W2 may be different from the first height H1 of the first partition wall W1. In detail, in an embodiment, the second height H2 of the second partition wall W2 may be smaller than the first height H1 of the first partition wall W1. A remaining area may be filled with the second color conversion pattern 720.

In an embodiment, the second scattering partition wall W22 may include a second scattering body SC2 and a second base resin BR2. The second scattering body SC2 may be in the dispersed form in the second base resin BR2.

A type of the second base resin BR2, a size of the second base resin BR2, a type of the second base resin BR2, or the like may be identical to the first scattering body SC1 and the first base resin BR1.

In an embodiment, the second color conversion pattern 720 may be formed through an inkjet process involving a second quantum dot QD2 and a second solvent. The second quantum dot QD2 may be in the dispersed form in the second solvent.

In other words, in an embodiment, the second color conversion pattern 720 does not include the scattering particle, and only the second scattering partition wall W22 may include the scattering particle (e.g., the second scattering particle SC2).

For example, the second color conversion pattern 720 may convert the light of the first wavelength band generated in the light-emitting layer 220 included in the second organic light-emitting diode OLED2 to the light of the second wavelength band. For example, light of wavelength belonging to about 450 nm to about 500 nm may be emitted from the light-emitting layer 220 on the second pixel electrode 210G. The light may be converted into light of wavelength belonging to about 520 nm to about 570 nm while passing through the second color conversion pattern 720. Thus, in the second sub-pixel PX2, light of wavelengths ranging from about 520 nm to about 570 nm may be emitted outward through the upper substrate 400. However, the disclosure is not limited thereto. As described above, the second organic light-emitting diode OLED2 may emit both light in the first and second wavelength bands.

In an embodiment, the second partition wall W2 may be disposed plurality in the second central opening COP2. For example, the second scattering partition wall W22 may be positioned twice to have a second critical dimension CD2 in the second central opening COP2. Similar to the above, for example, the second critical dimension CD2 may be between about 2 micrometers and about 3 micrometers. However, the disclosure is not limited thereto. For example, the second critical dimension CD2 value may vary depending on the size of the display device (e.g., the display device DD of FIG. 1).

In an embodiment, the color filter layer 500 may be arranged to cover the second partition wall W2. For example, at a position overlapping the second central opening COP2, the second color filter 520 may be continuously extended, and the first color filter 510 and the third color filter 530 may be partially removed to form a fifth opening. The width of the fifth opening (e.g., a width in the first direction DR1) may be smaller than the second critical dimension CD2. Accordingly, the increase in reflectivity by the second scattering partition wall W22 may be prevented or minimized.

In other words, the display device according to embodiments of the disclosure may minimize the increase in the reflectivity by having the light-shading area BP, in which the first color filter 510, the second color filter 520, and the third color filter 530 overlap each other, covers the second scattering partition wall W22.

Referring to FIGS. 4 and 6, in an embodiment, the second partition wall W2 (i.e., the second scattering partition wall W22) may be disposed one in the second central opening COP2. In an embodiment, the second partition wall W2 (i.e., the second scattering partition wall W22) may be nestled with a center CN2 of the second central opening COP2.

For example, a display device including the second scattering partition wall W22 overlapping the center CN2 of the second central opening COP2 may result in lower manufacturing costs than a display including plurality of second scattering partition walls W22. In addition, the second scattering partition wall W22 may scatter the light to uniformly adjust the brightness of the front and sides. In the case of the second scattering partition wall W22 of FIG. 6, it might not be covered by the color filters (e.g., the first color filter 510, the second color filter 520, and the third color filter 530).

In an embodiment, the third sub-pixel PX3 may include the third organic light-emitting diode OLED3 and the transparent pattern 730.

The transparent pattern 730 may be disposed in the third central opening COP3. The transparent pattern 730 may fill the third central opening COP3. The transparent pattern 730 may overlap the third central area CA3. The transparent pattern 730 may also overlap the third light-emitting area EA3.

The transparent pattern 730 may emit light generated from the light-emitting layer 220 included in the third organic light-emitting diode OLED3 to the outside without wavelength conversion while the transparent pattern 730 is included in the color conversion layer 700. For example, if light of wavelength belonging to about 450 nm to about 500 nm is generated in the light-emitting layer 220, the transparent pattern 730 may emit the light to the outside without the wavelength conversion.

In an embodiment, the transparent pattern 730 may include a third scattering body SC3 and a third base resin BR3. The third scattering body SC3 may be in a dispersed form in the third base resin BR3. For example, the transparent pattern 730 might not include the quantum dot.

A type of the third scattering body SC3, a size of the third scattering body SC3, and a type of the third base resin BR3 may be identical to the first scattering body SC1 and the first base resin BR1.

For example, the first quantum dot QD1 and the second quantum dot QD2 may have a core/shell structure.

For example, the core may act as a light-emitter that converts the wavelength of the light emitted from the light-emitting device. For example, the core may be formed by synthesizing group 12-16 elements. However, the disclosure is not limited thereto. For example, the core may be formed by synthesizing group 13-15 elements. For example, the core may include CdSe, CdS, InP, InxGa₍₁₋ₓ₎P, AgInₓGa₍₁₋ₓ₎S₂, AgInS₂, AgGaS₂, CuInS₂, CuInSe₂, CuGaS₂, CuGaSe₂, ZnS, ZnSe, ZnTeₓSe₍₁₋ₓ₎, or the like.

For example, if the core is included alone, a size of the core is nanoscale, a specific surface area is large, and there are many dangling bonds on the surface, which may create a trap inside a bandgap and result in a waste of energy non-radiative recombination that is emitted in a manner other than light (e.g., heat, electrons, or the like). To prevent this, the shell may surround the core. For example, the shell may be a protective layer that prevents chemical denaturation of the core and maintains semiconductor properties. In addition, the shell may act as a charging layer that imparts electrophoresis properties to the quantum dot.

For example, the shell may include a material having a bandgap slightly larger than the core. For example, the shell may include polyethylene glycol (“PEG”), polystyrene (“PS”), polymethyl methacrylate (“PMMA”), polyvinyl alcohol (“PVA”), or the like.

In an event of a mismatch of a lattice constant of the core and the shell, an internal defect may increase due to inter-stress. To prevent this, the shell may have a multi-shell structure. By having the multi-layer structure, the surface may be stabilized with the defect between the lattices minimized.

For example, the quantum dot may have a full width of half maximum (“FWHM”) of the light-emitting wavelength spectrum below about 45 nm, preferably below about 40 nm, and more preferably below about 30 nm. In addition, the light emitted from the quantum dot may be emitted in all directions, which may improve a light viewing angle.

For example, the quantum dot may adjust a color of the light emitted according to a particle size. Accordingly, the quantum dot may emit various colors such as blue, red, and green.

A second capping layer CL2 may be disposed on the first partition wall W1 and color conversion layer 700. The second capping layer CL2 may protect the first partition wall W1 and the color conversion layer 700. The second capping layer CL2 may prevent or minimize the penetration of impurities moisture, air, or the like from the outside to damage or contaminate the first partition wall W1 and/or the color conversion layer 700. For example, the second capping layer CL2 may include inorganic material.

The display device DD as described above may emit light in the third wavelength band from the first sub-pixel PX1 to the outside, light in the second wavelength band from the second sub-pixel PX2 to the outside, and light in the first wavelength band from the third sub-pixel PX3 to the outside. In other words, the display DD may display a full-color image.

For example, the connecting layer 30 may be disposed between the first panel 10 and the second panel 20. For example, the connecting layer 30 may be disposed between the encapsulation layer 300 and the first partition wall W1. The connecting layer 30 may act as a buffer against external pressure, or the like.

For example, the connecting layer 30 may include a filler. In an embodiment, the connecting layer 30 may include a thermoset or light-curable filler. For example, the filler may include methyl silicone, phenyl silicone, polyimide, urethane-based resin which is an organic sealant, epoxy resin, acrylic resin, inorganic sealant, or silicone. However, the disclosure is not limited thereto. For example, in the case of the display device including only one substrate (i.e., only the lower substrate 100), the connecting layer 30 may be omitted.

For example, a column spacer 800 may be disposed between the first panel 10 and the second panel 20. For example, the column spacer 800 may space the encapsulation layer 300 and the first partition wall W1. The column spacer 800 may penetrate the connecting layer 30.

For example, the column spacer 800 may include organic material. For example, the column spacer 800 may include an acrylic-based material.

For example, the column spacer 800 may space the light-emitting device and the color conversion layer 700 at uniform intervals. Accordingly, the connecting layer 30 may be disposed in the display area DA with uniform thickness. In other words, a distance at which the first organic light-emitting diode OLED1 and the first color conversion pattern 710 are spaced apart, a distance at which the second organic light-emitting diode OLED2 and the second color conversion pattern 720 are spaced apart, and a distance at which the third organic light-emitting diode OLED3 and the transparent pattern 730 are spaced apart may be substantially the same. As a result, depending on the position of the display area DA, the difference in brightness may be prevented or minimized. However, the disclosure is not limited thereto. For example, in the case of a display device including only one of substrate, the column spacer 800 may be omitted.

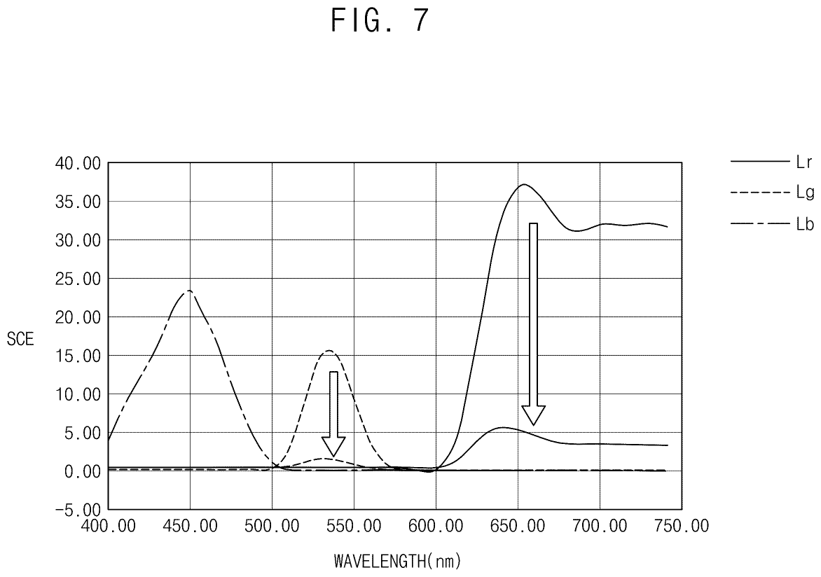

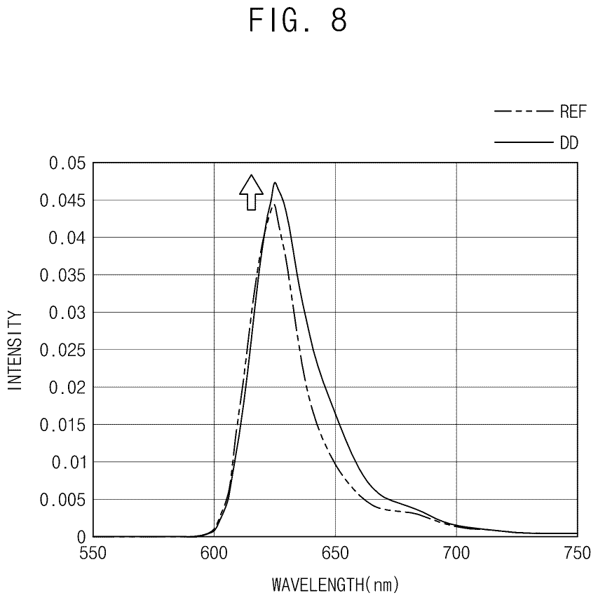

FIGS. 7 and 8 are views illustrating an effect of the display device according to embodiments of the disclosure.

For example, a X axis of FIG. 7 represents a wavelength, and a Y axis of FIG. 7 represents a reflectance of specular component excluded (“SCE”). The SCE is a measure of a diffuse reflectivity excluding a specular reflected light that light is incident on a surface of an object and reflected at the same angle. The X axis of FIG. 8 represents the wavelength, and the Y axis of FIG. 8 represents a brightness.

Referring to FIG. 7, in a case of a display device according to a comparative embodiment, the first color conversion pattern 710 and the second color conversion pattern 720 may include the scattering body. In this case, a portion of the external light passed through the first color filter 510 and the second color filter 520 may be reflected to the scattering body, and the reflectivity of the display device may be large. For example, the reflectivity of the first color-light Lr is about 35% or more, the reflectivity of the second color-light Lg is about 15% or more, and the third color-light Lb is about 20% or more.

However, in a case of a display device according to embodiments of the disclosure, the first color conversion pattern 710 and the second color conversion pattern 720 might not include the scattering body, so that the reflectivity of the display device DD may be reduced. In addition, the second partition wall W2 including the scattering body may be covered by the color filter layer 500 to prevent or minimize the increase in the reflectivity. For example, the reflectivity of the second color Lg is about 5% or less, and the third color-light Lb is within or outside about 5%. In other words, in the case of the display device according to embodiments of the disclosure, compared to the display device according to the comparative embodiment, a reflectivity reduction effect of about 70% in the first sub-pixel PX1 and a reflectivity reduction effect of about 90% in the second sub-pixel PX2 is shown.

Referring to FIG. 8, in the case of the display device according to the comparative embodiment, the scattering body may be dispersed in the first sub-pixel PX1 and the second sub-pixel PX2, so a frontal brightness may be small.

However, in the case of the display device according to embodiments of the disclosure, the first color conversion pattern 710 and the second color conversion pattern 720 might not include the scattering body, so that the front brightness (frontal transmittance) of the display device DD may be increased. In addition, as the second partition wall W2 includes the scattering body, surplus light may be absorbed by the quantum dot, which increases side scattering and further increases brightness.

In the case of the display device according to embodiments of the disclosure, the effect of increasing the brightness by about 8% compared to the display device according to the comparative embodiment is observed. For example, in a lateral portion of the first color conversion pattern 710, the quantum dot may absorb the surplus light (e.g., the second color-light (e.g., the green light) and the third color-light (e.g., the blue light), so that the brightness may be further increased.

In addition, in the case of the display device according to the comparative embodiment, when the first color conversion pattern 710 and the second color conversion pattern 720 are formed by the inkjet process, the scattering body may be adsorbed to the nozzle and the nozzle may deteriorate (e.g., clogging, adsorption, or the like). In addition, the ink including the scattering body has a high viscosity, which may cause a problem in that a landing range decreases as a drop volume increase.

However, in the case of a display device according to embodiments of the disclosure, the ink does not include the scattering body and the deterioration of the nozzle may be prevented. In addition, as the viscosity of the ink decreases, the drop volume may be reduced, and the inkjet process to form the display device of higher resolution may be carried out.

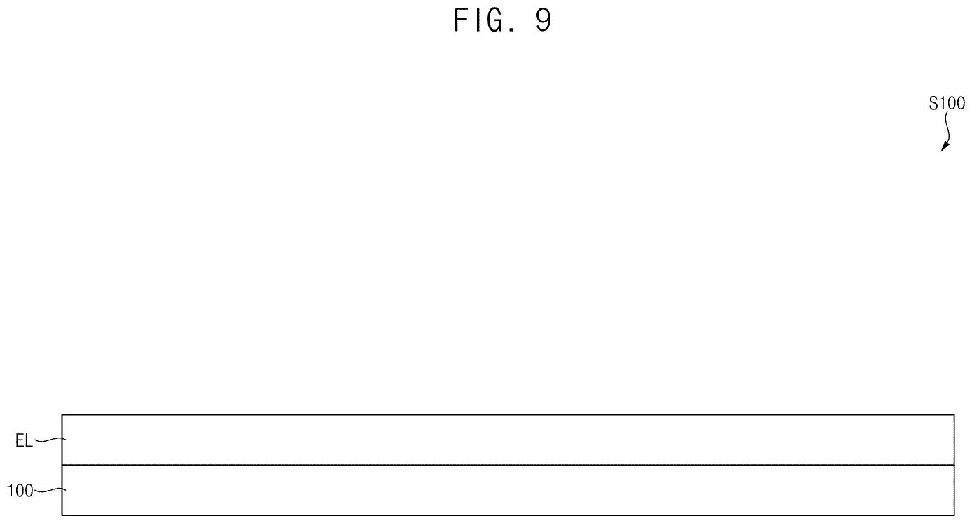

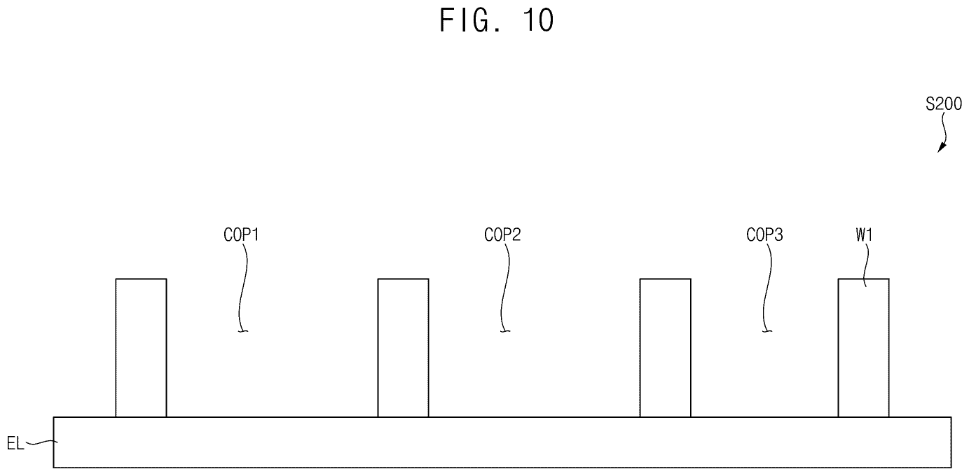

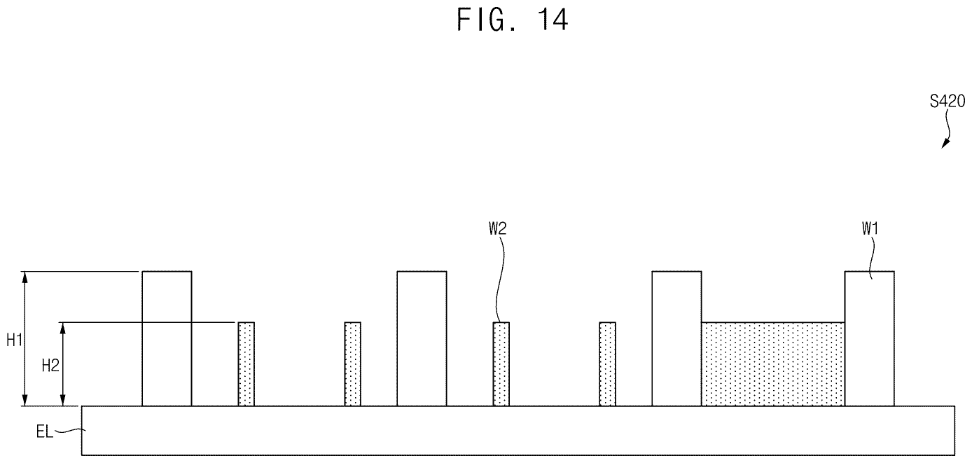

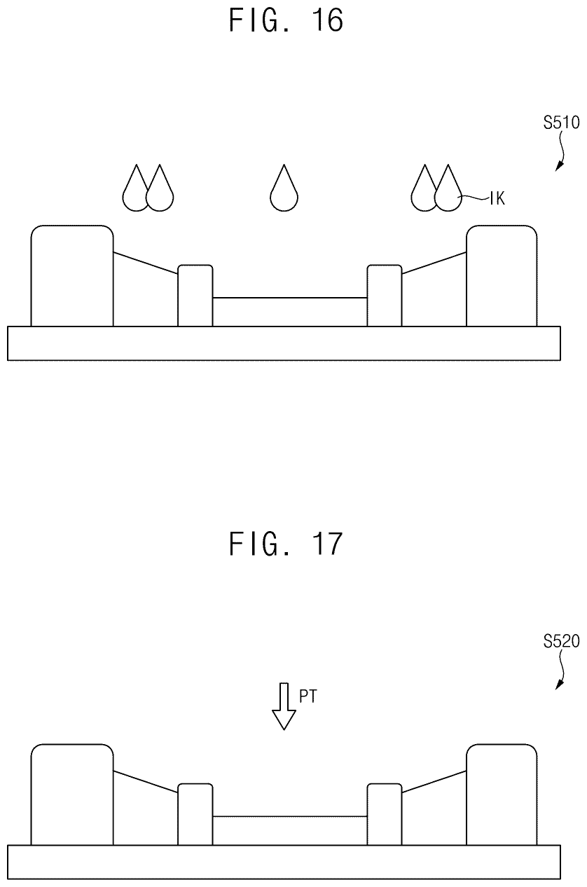

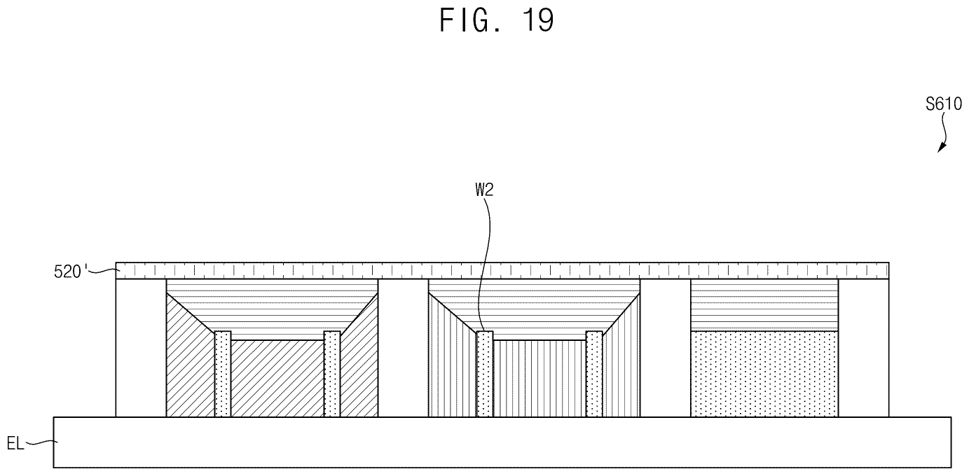

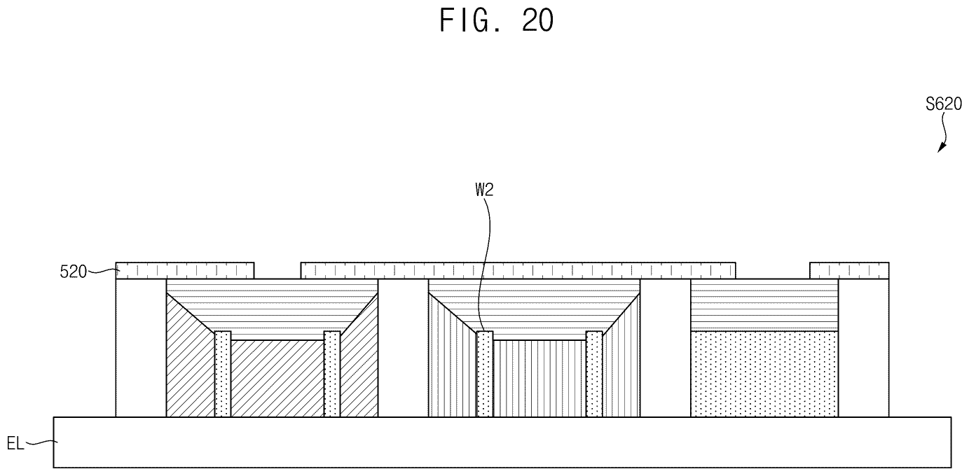

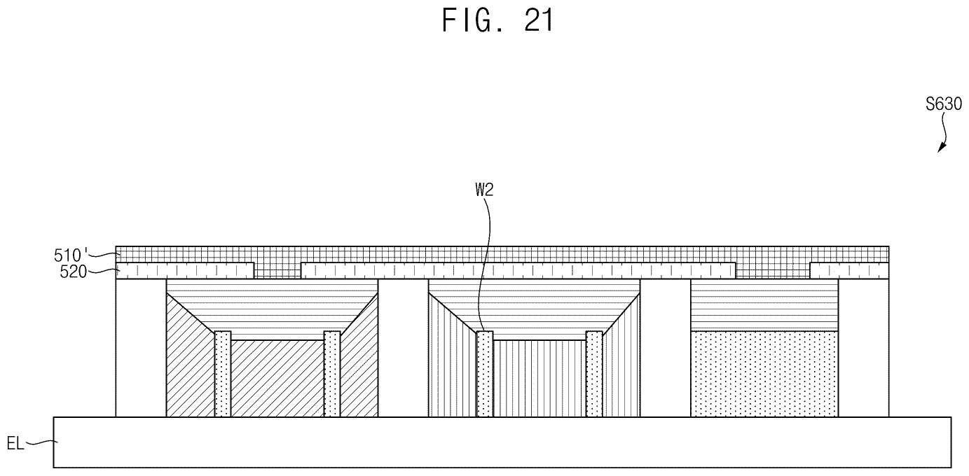

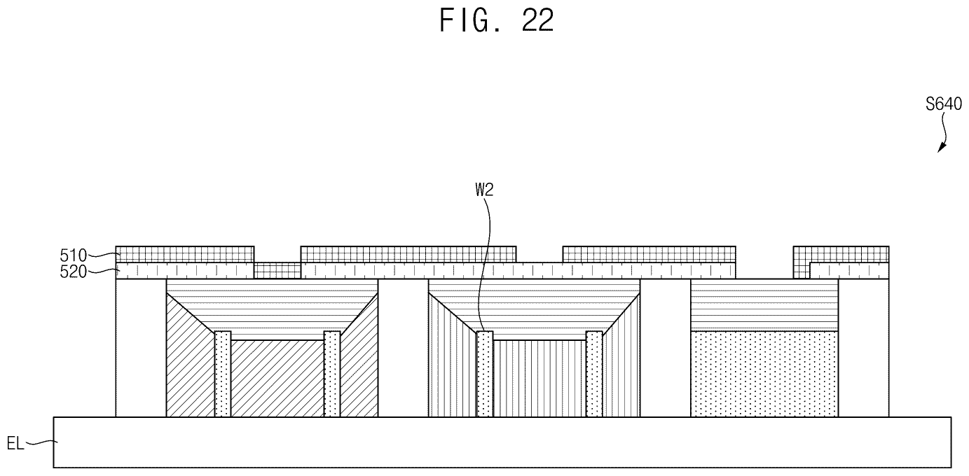

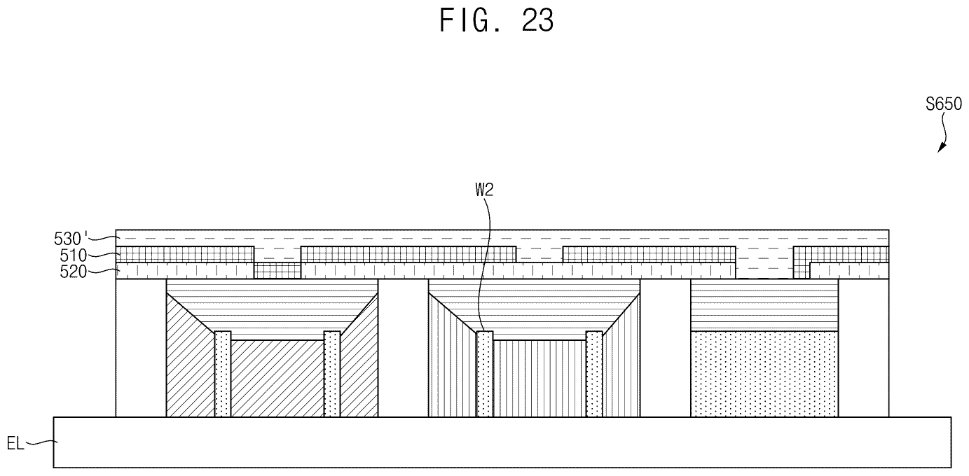

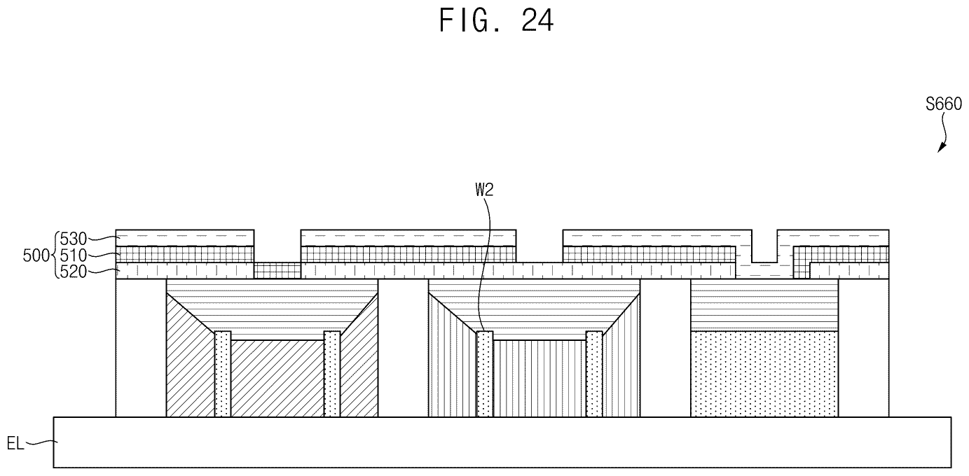

FIGS. 9, 10, 11, 12, 13, 14, 15, 16, 17, 18, 19, 20, 21, 22, 23, and 24 are views illustrating the manufacture method of the display device according to a first embodiment of the disclosure.

Hereinafter, for convenience of description, descriptions that overlaps with the description of the display device referring to FIGS. 1, 2, 3, 4, 5, 6, 7, and 8 may be omitted or simplified.

Referring to FIGS. 4, 5, 6, 7, 8, and 9, the light-emitting layer EL may be formed on substrate 100 including the first light-emitting area EA1, the second light-emitting area EA2, the third light-emitting area EA3, and the light-shading area (e.g., the area between the first and third light-emitting areas EA1, EA2, and EA3 surrounding the first to third light-emitting areas EA1, EA2, and EA3) (S100).

As described above, the substrate 100 may also be the upper substrate (e.g., upper substrate 400 of FIG. 4). In this case, the color filter layer (e.g., 500 of FIG. 4) may be formed on the upper substrate, and then the color conversion layer (e.g., 500 of FIG. 4) may be formed.

Hereinafter, the substrate 100 may correspond to the lower substrate 100 of FIG. 4. The light-emitting layer EL may be formed on the lower substrate 100, and the processes described below may be carried out.

In other words, the following steps are not described in chronological order.

Referring to FIGS. 5, 6, and 10, the first partition wall W1 may be formed on the light-emitting layer EL, overlapping the light-shading area, having the first height H1, defining the first central opening COP1 overlapping the first light-emitting area, the second central opening COP2 overlapping the second light-emitting area, and the third central opening COP3 overlapping the third light-emitting area (S200).

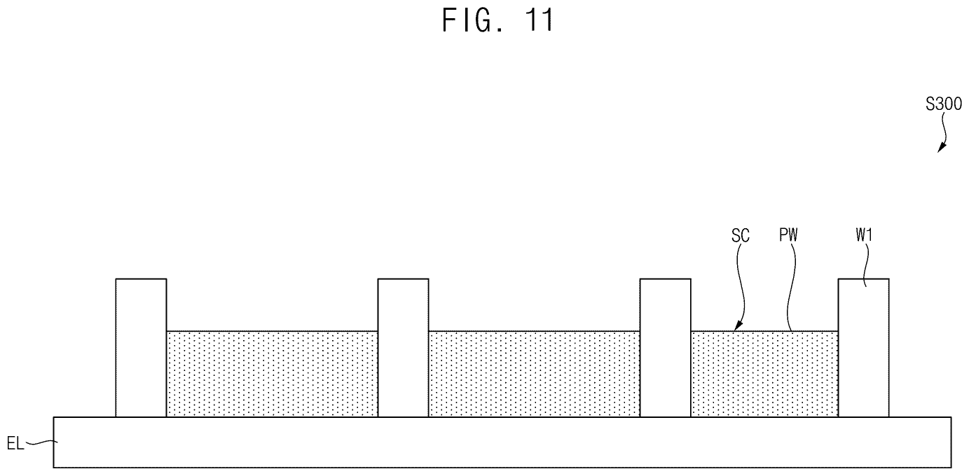

Referring to FIG. 11, a preliminary partition wall layer PW including the scattering body SC in the first central opening, the second central opening, and the third central opening (S300). As described above, the scattering body SC may be in the dispersed form in the solvent.

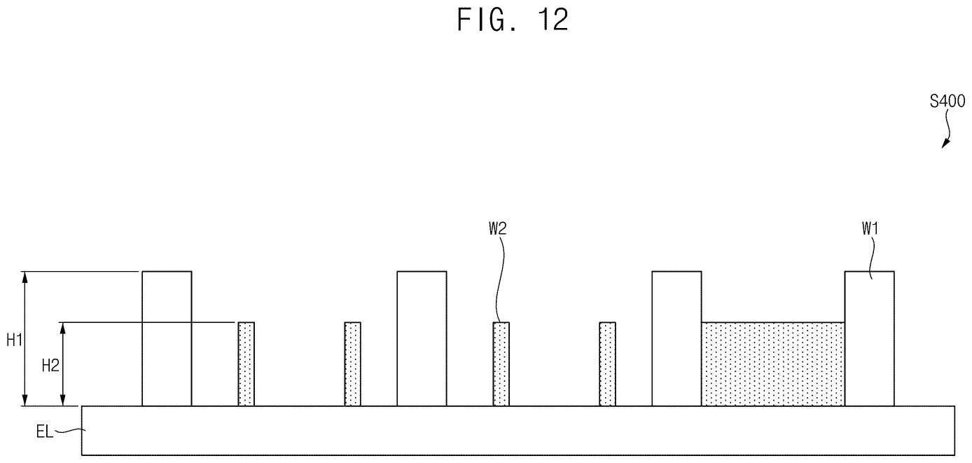

Referring to FIGS. 12, 13, and 14, a portion of the preliminary partition wall layer PW in the first central opening and the second central opening may be removed to form the second partition wall W2 (S400). The steps to form the second partition wall (S400) may include, forming a half-tone mask MA on the preliminary partition wall layer PW (S410) and patterning the preliminary partition wall layer PW to have the second height H2 that is smaller than the first height H1 of the first partition wall W1 using the half-tone mask MA (S420).

For example, the patterning process may be formed using the half-tone mask MA and light exposed through the half-tone mask MA. However, the disclosure is not limited thereto. Here, the preliminary partition wall layer PW in the third central opening might not be removed, or may only be thinned.

Thereby, in the first central opening and the second central opening, the second partition wall W2 may be disposed, and the preliminary partition wall layer PW in the third central opening may be the transparent pattern (e.g., the transparent pattern 730 of FIG. 4).

The second partition wall W2 may be adjacent to the first partition wall W1 or spaced apart. For example, if the first partition wall W1 and the second partition wall W2 are spaced apart, it may be easy to adjust the thickness of the color conversion patterns described below.

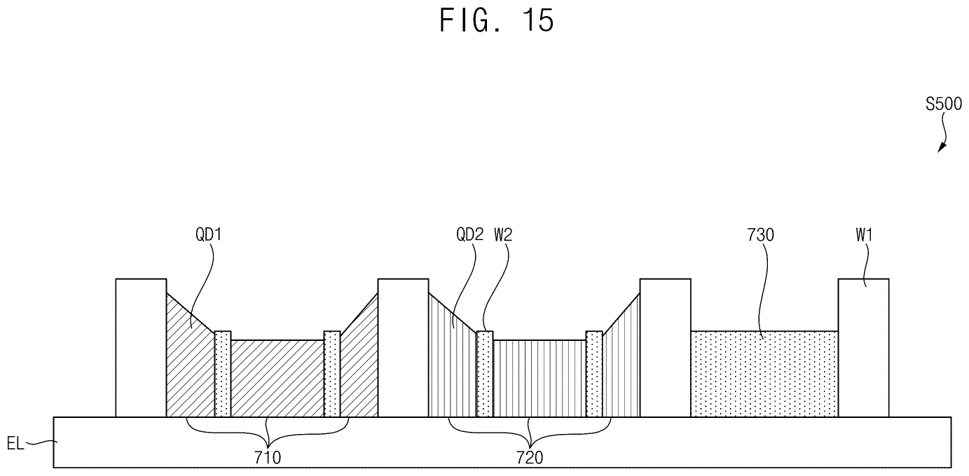

Referring to FIGS. 15, 16, and 17, it is possible to form the first color conversion pattern 710 covering the second partition wall W2 in the first central opening and including the ink without the scattering body and the second color conversion pattern 720 covering the second partition wall W2 in the second central opening and including the ink without the scattering body (S500). The steps to form the first color conversion pattern 710 and the second color conversion pattern 720 (S500) may include jetting an ink IK without the scattering body in the first opening and the second opening (S510), and exposing PT the ink IK (S520).

Here, the ink IK may include the quantum dots QD1, QD2 and does not include the scattering body SC. Accordingly, the adsorption of scattering body SC to the nozzle used in the inkjet process may be prevented. Therefore, the deterioration of the nozzle may be further prevented.

In addition, the ink IK without the scattering body SC may have lower viscosity than the ink IK that includes the scattering body SC. Accordingly, the larger drop volume allows for the more precise inkjet process.

For example, the ink IK may be applied to an outer portion surrounding the center portion more than to the central portion of the first central opening. In other words, a thickness of the center portion of the first to second color conversion patterns may be thinner than a thickness of the outer portion. For example, if a light source (the first color light) is strong from the front, a light source of the side (the second color light/the third color light) may scatter the more inks IK to display the image in the desired color, and increase the brightness.

In other words, the thickness of the second color conversion patterns 710, 720 may be adjusted for each position relative to the second partition wall W2. Accordingly, the display device with improved display property (increased frontal transmittance, increased brightness due to lateral scattering, and reduced reflectivity) may be formed.

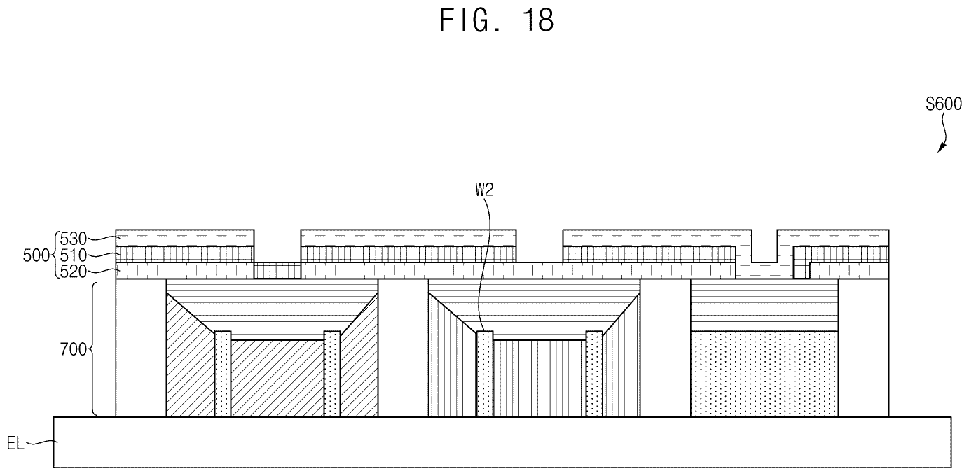

Referring to FIGS. 18, 19, 20, 21, 22, 23, and 24, the method may further include forming the color filter layer 500 (S600). The forming of the color filter layer 500 (S600) may further includes, if the second partition wall W2 is disposed plurality in each of the first central opening and the second central opening, forming a second preliminary color filter layer 520′ on the color conversion layer (S610), forming a second color filter layer 520 by removing a portion of the second preliminary color filter layer 520′ to cover the plurality of second partition walls W2, and overlapping a portion of the first central opening, an entirety of the second central opening, and a portion of the third central opening (S620), forming a first preliminary color filter layer 510′ on a second color filter layer 520 (S630), forming a first color filter layer 510 by removing a portion of the first preliminary color filter layer 510′ to cover the plurality of second partition walls W2, and overlap an entirety of the first central opening, a portion of the second central opening, and a portion of the third central opening (S640), forming a third preliminary color filter layer 530′ on the first color filter layer 510 (S650), and forming a third color filter layer 530 by removing a portion of the third preliminary color filter layer 530′ to cover the plurality of second partition walls W2, and overlap a portion of the first central opening, a portion of the second central opening, and an entirety of the third central opening (S660).

The display device manufactured thereby may act as a black matrix (e.g., BP of FIG. 4) by overlapping the first to third color filters 510, 520, and 530 to prevent or minimize the increase in reflectivity. Since the second partition wall W2 (i.e., the scattering body) is not located in the center of the openings, the light source that may go outside may increase, so that the brightness maybe increased.

In addition, since the first and second color conversion patterns 710, 720 does not include the scattering body SC, the reflectivity may be further reduced.

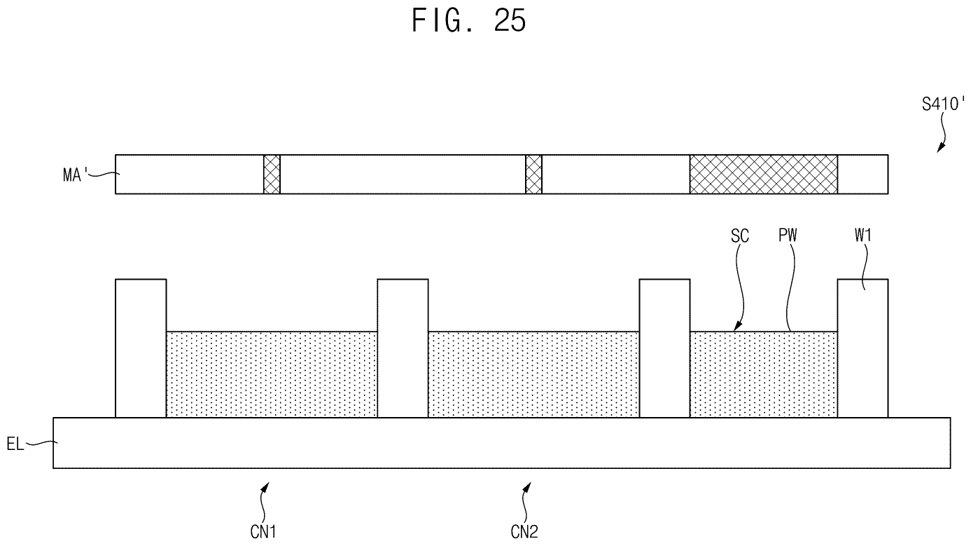

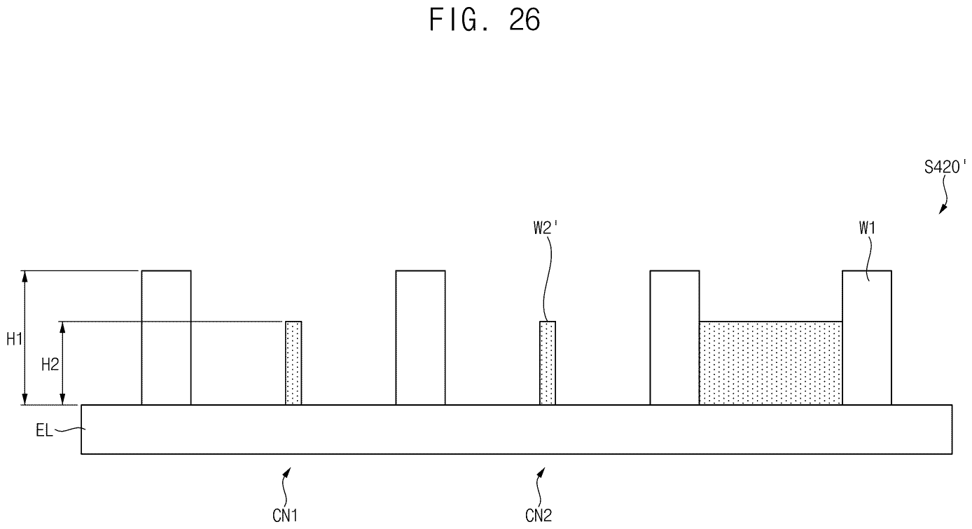

FIGS. 25 and 26 are views illustrating the manufacturing method of the display device according to a second embodiment of the disclosure.

Hereinafter, for convenience of the description, the description that overlaps with the description of the display device with reference to FIGS. 1, 2, 3, 4, 5, 6, 7, and 8 and the description of the manufacturing method of the display device with reference to FIGS. 9, 10, 11, 12, 13, 14, 15, 16, 17, 18, 18, 20, 21, 22, 23, and 24 may be omitted or simplified.

Referring to FIGS. 6, 25, and 26, the forming of the second partition wall W2′ (S400′) may include, forming a half-tone mask MA′ on the preliminary partition wall layer PW (S410′) and patterning the preliminary partition wall layer PW to have the second height H2 smaller than the first height H1 of the first partition wall W1. One first scattering partition wall W21′ overlapping the center CN1 of the first central opening and one second scattering partition wall W22′ overlapping the center CN2 of the second central opening may be formed (S420′).

The display device manufactured thereby may be substantially identical to the display with reference to FIGS. 9, 10, 11, 12, 13, 14, 15, 16, 17, 18, 19, 20, 21, 22, 23, and 24, except that a location of the scattering partition wall, number of the scattering partition wall, and the scattering partition wall is not covered by color filter.

If the second partition wall W2 is formed one at the center of the first central opening CN1 and one at the center of the second central opening CN2, the manufacturing cost may be further reduced.

In addition, by proceeding with the process without considering the critical dimensions (e.g., CD1, CD2 of FIG. 5), the process may be further streamlined (e.g., alignment time reduced).

In addition, the second partition wall W2 is located in the center (e.g., the center CN1 of the first central opening and the center CN2 of the second central opening), which allows for further improvement of the forward lateral brightness ratio (i.e., white angle dependency, “WAD”) property.

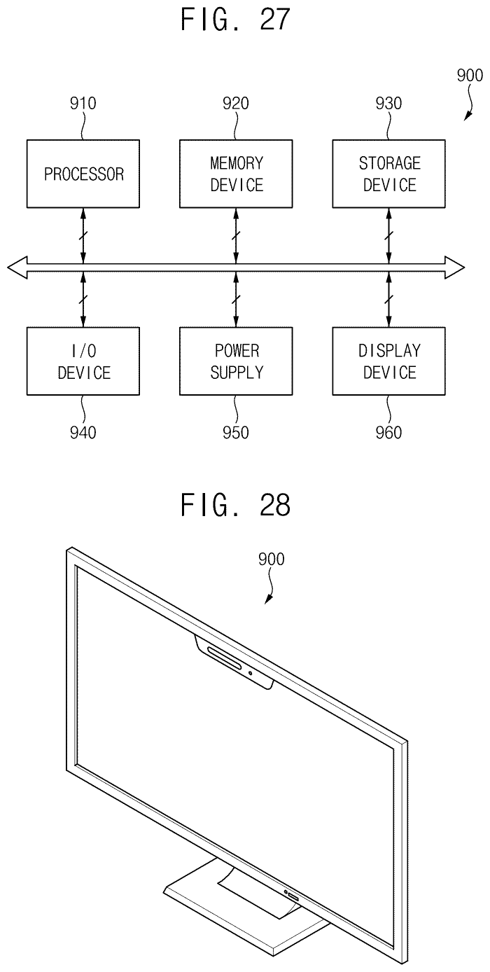

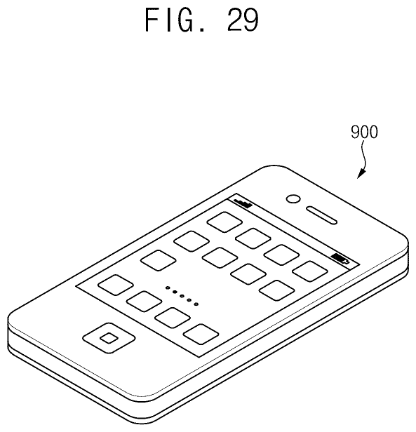

FIG. 27 is a block diagram illustrating an electronic device including the display device of FIG. 1. FIG. 28 is a view illustrating an example in which the electronic device of FIG. 27 is implemented as a television. FIG. 29 is a view illustrating an example in which the electronic device of FIG. 27 is implemented as a smartphone.

Hereinafter, for convenience of explanation, descriptions overlapping with the descriptions of the display device described above with reference to FIGS. 1, 2, 3, 4, 5, 6, 7, and 8 and the manufacturing method of the display device described above with reference to FIGS. 9, 10, 11, 12, 13, 14, 15, 16, 17, 18, 19, 20, 21, 22, 23, 24, 25, and 26 may be omitted or simplified.

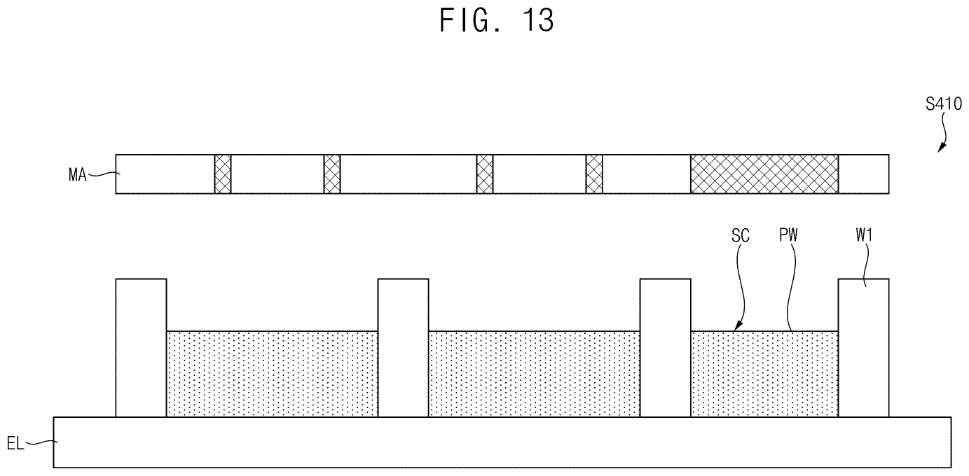

Referring to FIGS. 13, 14, and 15, in an embodiment, an electronic device 900 may include a processor 910, a memory device 920, a storage device 930, an input/output device 940, a power supply 950, and a display device 960. In this case, the display device 960 may correspond to the display device DD described with reference to FIGS. 1, 2, 3, 4, 5, 6, 7, and 8. The electronic device 900 may further include several ports capable of communicating with a video card, a sound card, a memory card, a USB device, or the like. The display device 960 may be connected to another components through the buses and other communicating port. As described above, the color conversion pattern might not include the scattering body and the partition wall may include the scattering body in the display device 960.

In an embodiment, as shown in FIG. 28, the electronic device 900 may be implemented as a television. In another embodiment, as shown in FIG. 29, the electronic device 900 may be implemented as a smartphone. However, the electronic device 900 is not limited thereto. For example, the electronic device 900 may be implemented as a mobile phone, a smart phone, a smart watch, a tablet computer, a digital television, a 3D television, a virtual reality device (e.g., head mounted display, “HMD”), a personal computer (“PC”), a home electronic device, a notebook computer, a personal digital assistance (“PDA”), a portable multimedia player (“PMP”), a digital camera, an MP3 player, a portable game console, a navigation system, or the like.

It may be implemented in a mobile phone, a video phone, a smart pad, a smart watche, a tablet PC, a car navigation system, a computer monitor, a laptop, a head mounted display (“HMD”), or the like.

The processor 910 may perform certain calculations or tasks. The processor may control the display device 960. In an embodiment, the processor 910 may be a microprocessor, a central processing unit (“CPU”), an application processor (“AP”), or the like. The processor 910 may be connected to other components through an address bus, a control bus, a data bus, or the like. The processor 910 may also be connected to an expansion bus, such as a peripheral component interconnect (“PCI”) bus.

The memory device 920 may store data necessary for the operation of the electronic device 900. For example, the memory device 920 may include an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a non-volatile memory device such as a ferroelectric random access memory (“FRAM”) device and/or a volatile memory device such as a dynamic random access memory (“DRAM”) device, a static random access memory (“SRAM”) device, and a mobile DRAM device, or the like.

The storage device 930 may include a solid state drive (“SSD”), a hard disk drive (“HDD”), a CD-ROM, or the like.

The input/output device 940 may include input means such as a keyboard, keypad, touch pad, touch screen, mouse, and the like and output means such as a speaker, a printer, or the like.

The power supply 950 may supply power necessary for the operation of the electronic device 900. The display device 960 may be connected to other components through buses or other communication links. In an embodiment, the display device 960 may be included in the input/output device 940.

In the display device and the electronic device including the display device according to embodiments of the disclosure, the partition wall including the scattering body and the color conversion pattern not including the scattering body may be confirmed in the cross-sectional view. For example, the partition wall including the scattering body and the color conversion pattern not including the scattering body may be confirmed using a scanning electron microscope (“SEM”), a transmission electron microscope (“TEM”), or the like.

The disclosure may be applied to a mobile phone, a smartphone, a smart pad, a television, a digital television, a 3D television, a personal computer, a home electronic device, a notebook computer, a personal digital assistance “PDA”, a portable media player “PMP”, a digital camera, an MP3 player, a portable game console, a navigation system, or the like.

The disclosure should not be construed as being limited to the embodiments set forth herein. Rather, these embodiments are provided so that this disclosure will be thorough and complete and will fully convey the concept of the disclosure to those skilled in the art. While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A display device including:
a substrate including a first light-emitting area, a second light-emitting area, a third light-emitting area, and a non-light-emitting area surrounding the first light-emitting area, the second light-emitting area, and the third light-emitting area in a plan view;
a first partition wall overlapping the non-light-emitting area on the substrate, having a first height, and defining a first central opening overlapping the first light-emitting area, a second central opening overlapping the second light-emitting area, and a third central opening overlapping the third light-emitting area in the plan view;
a second partition wall including a first scattering partition wall disposed in the first central opening and a second scattering partition wall disposed in the second central opening, having a second height different from the first height, and including a scattering body;
a color conversion layer including a first color conversion pattern, a second color conversion pattern, and a transparent pattern, wherein,
the first color conversion pattern is disposed adjacent to the first scattering partition wall in the first central opening and including an ink without the scattering body,
the second color conversion pattern is disposed adjacent to the second scattering partition wall in the second central opening and including the ink without the scattering body,
the transparent pattern is disposed in the third central opening; and
a light-emitting layer disposed between the substrate and the color conversion layer.

2. The display device of claim 1, wherein the scattering body includes at least one or more oxides selected from a group consisting of TiO₂, SiO₂, BaSO₄, ZnO, Al₂O₃, and CaCO₃.

3. The display device of claim 1, wherein the second height is smaller than the first height.

4. The display device of claim 1, further including a color filter layer on the color conversion layer,
wherein the color filter layer includes:
a first color filter overlapping the first central opening in the plan view,
a second color filter overlapping the second central opening in the plan view, and
a third color filter overlapping the third central opening in the plan view.

5. The display device of claim 4, wherein the second partition wall is provided in plurality in each of the first central opening and the second central opening.

6. The display device of claim 5, wherein the first color filter, the second color filter, and the third color filter cover the plurality of the second partition walls.

7. The display device of claim 1, wherein the second partition wall is provided in singularity in each of the first central opening and the second central opening.

8. The display device of claim 7, wherein the second partition wall is disposed to overlap each of a center of the first central opening and a center of the second central opening.

9. An electronic device including a display device and a processor, which controls the display device,
wherein the display device includes:
a substrate including a first light-emitting area, a second light-emitting area, a third light-emitting area, and a non-light-emitting area surrounding the first light-emitting area, the second light-emitting area, and the third light-emitting area in a plan view;
a light-emitting layer on the substrate;
a first partition wall overlapping the non-light-emitting area on the light-emitting layer, having a first height, and defining a first central opening overlapping the first light-emitting area, a second central opening overlapping the second light-emitting area, and a third central opening overlapping the third light-emitting area in the plan view;
a second partition wall including a first scattering partition wall disposed in the first central opening and a second scattering partition wall disposed in the second central opening, having a second height different from the first height, and including a scattering body;
a color conversion layer including a first color conversion pattern, a second color conversion pattern, and a transparent pattern, wherein,
the first color conversion pattern is disposed adjacent to the first scattering partition wall in the first central opening and including an ink without the scattering body,
the second color conversion pattern is disposed adjacent to the second scattering partition wall in the second central opening and including the ink without the scattering body, and
the transparent pattern is disposed in the third central opening; and
a color filter layer disposed on the color conversion layer, and including a first color filter overlapping the first central opening, a second color filter overlapping the second central opening, and a third color filter overlapping the third central opening in the plan view.

10. The electronic device of claim 9, wherein the scattering body includes at least one or more oxides selected from a group consisting of TiO₂, SiO₂, BaSO₄, ZnO, Al₂O₃, and CaCO₃.

11. The electronic device of claim 9, wherein the second height is smaller than the first height.

12. The electronic device of claim 9, wherein the second partition wall is provided in plurality in each of the first central opening and the second central opening.

13. The electronic device of claim 12, wherein the first color filter, the second color filter, and the third color filter cover the plurality of the second partition walls.

14. The electronic device of claim 9, wherein the second partition wall is provided in singularity in each of the first central opening and the second central opening.

15. The electronic device of claim 14, wherein the second partition wall includes: one first scattering partition wall overlapping a center of the first central opening and one second scattering partition wall overlapping a center of the second central opening in the plan view.

16. A manufacturing method of a display device, the method including:
forming a light-emitting layer on a substrate including a first light-emitting area, a second light-emitting area, a third light-emitting area, and a non-light-emitting area surrounding the first light-emitting area, the second light-emitting area, and the third light-emitting area in a plan view;
forming a first partition wall on the light-emitting layer, overlapping the non-light-emitting area, having a first height, and defining a first central opening overlapping the first light-emitting area, a second central opening overlapping the second light-emitting area, and a third central opening overlapping the third light-emitting area in the plan view;
forming a preliminary partition wall including a scattering body in the first central opening, the second central opening, and the third central opening;
forming a second partition wall by removing a portion of the preliminary partition wall in the first central opening and the second central opening; and
forming a first color conversion pattern and a second color conversion pattern, wherein the first color conversion pattern is formed adjacent to the second partition wall in the first central opening and includes ink without the scattering body, and the second color conversion pattern is formed adjacent to the second partition wall in the second central opening and includes the ink without the scattering body.

17. The method of claim 16,
wherein the forming of the first color conversion pattern and the second color conversion pattern includes:
jetting the ink without the scattering body in the first opening and the second opening; and
exposing the ink.

18. The method of claim 16,
wherein the forming of the second partition wall includes:
forming a mask on the preliminary partition wall; and
forming the second partition wall in plurality by patterning the second partition wall to have a second height smaller than the first height of the first partition wall using the mask.

19. The method of claim 16, in case the second partition wall is provided in plurality in each of the first central opening and the second central opening, further including:
forming a second preliminary color filter layer on the color conversion layer; and
forming a second color filter layer by removing a portion of the second preliminary color filter layer to cover the plurality of the second partition walls and overlap a portion of the first central opening, an entirety of the second central opening, and a portion of the third central opening in the plan view;
forming a first preliminary color filter layer on the second color filter layer;
forming a first color filter layer by removing a portion of the first preliminary color filter layer to cover the plurality of the second partition walls and overlap an entirety of the first central opening, a portion of the second central opening, and a portion of the third central opening in the plan view;
forming a third preliminary color filter layer on the first color filter layer; and
forming a third color filter layer by removing a portion of the third preliminary color filter layer to cover the plurality of the second partition walls and overlap a portion of the first central opening, a portion of the second central opening, and an entirety of the third central opening in the plan view.

20. The method of claim 16,
wherein the forming of the second partition wall includes:
forming a mask on the preliminary partition wall; and
forming one first scattering partition wall and one second scattering partition wall by patterning the second partition wall to have a second height smaller than the first height of the first partition wall using the mask,
wherein the first scattering partition wall overlaps the first central opening and the second scattering wall overlaps the second central opening in the plan view.
